(19) United States
(12) Patent Application Publication
(10) Pub. No.: US 2026/0271516 A1
(43) Pub. Date: Sep. 10, 2026

(54) APPARATUS AND METHOD FOR FABRICATING DISPLAY DEVICE, AND DISPLAY DEVICE

(71) Applicant: Samsung Display Co., LTD., Yongin-si (KR)

(72) Inventors: Sang Moo LEE, Yongin-si (KR); Gyu Tae KIM, Yongin-si (KR); Min Suk KIM, Yongin-si (KR); Hyun Jin KIM, Yongin-si (KR); Kyoung Jae LEE, Yongin-si (KR)

(21) Appl. No.: 19/380,113

(22) Filed: Nov. 5, 2025

(30) Foreign Application Priority Data
Mar. 10, 2025 (KR) 10-2025-0030442

(51) Int. Cl. H10K 59/12; H10K 71/13; H10P 74/00

(52) U.S. Cl. CPC H10K 59/1201; H10K 71/135; H10P 74/235

(57) ABSTRACT

Embodiments include an apparatus and method for fabricating a display device and display device manufactured by the method. The apparatus for fabricating the display device, includes: a stage on which a substrate is placed; a sensor unit configured to acquire data by capturing an image of the substrate and the stage and/or measuring numerical values; a pattern generating unit configured to analyze the data to calculate a size of the substrate and position information of the substrate relative to the stage, and to create a pattern map based on the size and position information of the substrate; and an inkjet head unit comprising at least one inkjet head, which ejects ink onto the substrate based on the pattern map, where the substrate on which the ink has been applied is attached on a surface of a display panel of the display device.

### CROSS REFERENCE TO RELATED APPLICATIONS

This application claims priority to Korean Patent Application No. 10-2025-0030442 filed on Mar. 10, 2025, and all the benefits accruing therefrom under 35 U.S.C. §119, the content of which in its entirety is herein incorporated by reference.

### BACKGROUND

### 1. Field of the Disclosure

The present disclosure relates to an apparatus for fabricating a display device, a method for fabricating a display device, and a display device.

### 2. Description of the Related Art

As the information-oriented society evolves, various demands for display devices are ever increasing. A display device may be a flat-panel display device such as a liquid-crystal display device, a field emission display device, and a light-emitting display device. Light-emitting display devices may include an organic light-emitting display device including organic light-emitting emitting diodes as light-emitting elements, or an light-emitting diode display device including inorganic light-emitting diodes such as light-emitting diodes (LEDs) as light-emitting elements.

A display device may include a cover window for protecting the display panel. The cover window may be attached to the display panel using an optically clear adhesive. The optically clear adhesive may be applied onto the display panel by using an inkjet printing technique or a roller.

### SUMMARY

Aspects of the present disclosure provide an apparatus for fabricating a display device that can apply an optically clear adhesive in an appropriate amount to an accurate location on a substrate using a pattern map based on the size and location of the substrate.

It should be noted that aspects of the present disclosure are not limited to the above-mentioned aspect; and other aspects of the present disclosure will be apparent to those skilled in the art from the following descriptions.

According to an aspect of the present disclosure, there is provided an apparatus for fabricating a display device, the apparatus including: a stage on which a substrate is placed; a sensor unit configured to acquire data by capturing an image of the substrate and the stage and/or measuring numerical values; a pattern generating unit configured to analyze the data to calculate a size of the substrate and position information of the substrate relative to the stage, and to create a pattern map based on the size and position information of the substrate; and an inkjet head unit including at least one inkjet head, which ejects ink onto the substrate based on the pattern map, where the substrate on which the ink has been applied is attached on a surface of a display panel of the display device.

The data may include a line image of the substrate, which is obtained by capturing an image of edges of the substrate.

The stage may include a first alignment mark and a second alignment mark, wherein the first alignment mark may include a first sub-mark extended in a first direction and a second sub-mark extended in a second direction intersecting the first direction, and wherein the second alignment mark may include a third sub-mark extended in the first direction and a fourth sub-mark extended in the second direction.

The pattern generating unit may measure a first distance between the first sub-mark and a first side of the line image, and a second distance between the second sub-mark and a second side of the line image, and may measure a third distance between the third sub-mark and the first side of the line image, and a fourth distance between the fourth sub-mark and a third side of the line image.

The pattern generating unit may measure a first angle formed by a first virtual line extended in the first direction from the first sub-mark and a second virtual line extended from the second side of the line image, and a second angle formed by a third virtual line extended in the second direction from the second sub-mark and a fourth virtual line extended from the first side of the line image, and may measure a third angle formed by a fifth virtual line extended in the first direction from the third sub-mark and a sixth virtual line extended from the third side of the line image, and a fourth angle formed by a seventh virtual line extended in the second direction from the fourth sub-mark and the fourth virtual line extended from the first side of the line image.

The position information of the substrate relative to the stage may be calculated based on information of the first distance, the second distance, the third distance, the fourth distance, the first angle, the second angle, the third angle and the fourth angle.

The apparatus may further include a light irradiating unit spaced apart from the inkjet head unit in a certain direction and configured to irradiate light.

The apparatus may further include an aligning unit located before the sensor unit and configured to align the substrate placed on the stage.

The sensor unit may include at least one of a line scan camera, a vision camera, and a laser camera.

The pattern generating unit may create the pattern map by adding/subtracting an offset to/from the size and position information of the substrate.

The apparatus may further include a stage moving unit for moving the stage in a certain direction.

According to an aspect of the present disclosure, there is provided a method for fabricating a display device, the method including: placing a substrate on a stage; acquiring data by capturing an image of the substrate and the stage and/or measuring numerical values; calculating a size of the substrate and position information of the substrate relative to the stage by analyzing the data; creating a pattern map based on the size and position information of the substrate; ejecting ink onto the substrate based on the pattern map; and attaching the substrate on which the ink has been ejected on a surface of a display panel of the display device.

The data may include a line image of the substrate, which is obtained by capturing an image of edges of the substrate with a line scan camera.

The stage may include a first alignment mark and a second alignment mark, wherein the first alignment mark may include a first sub-mark extended in a first direction and a second sub-mark extended in a second direction intersecting the first direction, and wherein the second alignment mark may include a third sub-mark extended in the first direction and a fourth sub-mark extended in the second direction.

The calculating the position information of the substrate relative to the stage includes: measuring a first distance between the first sub-mark and a first side of the line image, and a second distance between the second sub-mark and a second side of the line image; and measuring a third distance between the third sub-mark and the first side of the line image, and a fourth distance between the fourth sub-mark and a third side of the line image.

The calculating the position information of the substrate relative to the stage may further include: measuring a first angle formed by a first virtual line extended in the first direction from the first sub-mark and a second virtual line extended from the second side of the line image, and a second angle formed by a third virtual line extended in the second direction from the second sub-mark and a fourth virtual line extended from the first side of the line image; and measuring a third angle formed by a fifth virtual line extended in the first direction from the third sub-mark and a sixth virtual line extended from the third side of the line image, and a fourth angle formed by a seventh virtual line extended in the second direction from the fourth sub-mark and the fourth virtual line extended from the first side of the line image.

The calculating of the position information of the substrate relative to the stage may further include: calculating the position information of the substrate relative to the stage based on information of the first distance, the second distance, the third distance, the fourth distance, the first angle, the second angle, the third angle and the fourth angle.

The method may further include: prior to the acquiring of the data, aligning the substrate.

According to an aspect of the present disclosure, there is provided an electronic device including: a display device providing an image; and a processor transmitting an image data signal to the display device, wherein the display device is fabricated by: placing a substrate on a stage; acquiring data by capturing an image of the substrate and the stage and/or measuring numerical values; calculating a size of the substrate and position information of the substrate relative to the stage by analyzing the data; creating a pattern map based on the size and position information of the substrate; ejecting ink onto the substrate based on the pattern map; and attaching the substrate on which the ink has been ejected on a surface of a display panel of the display device.

According to an embodiment of the present disclosure, a pattern map is created based on the size of a substrate and the position of the substrate relative to a stage in an apparatus for fabricating a display device, so that an appropriate amount of ink can be ejected onto the substrate to fit the size of the substrate. Because the pattern map created according to the actual size of the substrate is used rather than any pre-set pattern map, it is possible to prevent the ink from being ejected onto the substrate overly or insufficiently.

In addition, an appropriate pattern map can be created on the substrate without any alignment process.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view showing a display device according to an embodiment of the present disclosure.

FIG. 2 is a cross-sectional view taken along line A1 – A1' of FIG. 1.

FIG. 3 is a cross-sectional view showing an example of a display panel according to an embodiment of the present disclosure.

FIGS. 4A-4C are plan views showing examples of polarizing plates of different sizes according to an embodiment.

FIGS. 5A-5C are views showing the polarizing plate of FIG. 4A and an adhesive member applied on the polarizing plate.

FIG. 6 is a cross-sectional view taken along line A2 – A2' of FIG. 5C.

FIGS. 7A and 7B are views showing the polarizing plate of FIG. 4B and an adhesive member applied on the polarizing plate.

FIG. 8 is a cross-sectional view taken along line A3 – A3' of FIG. 7B.

FIGS. 9A and 9B are views showing the polarizing plate of FIG. 4C and an adhesive member applied on the polarizing plate.

FIG. 10 is a cross-sectional view taken along line A4 - A4' of FIG. 9B.

FIG. 11 is a perspective view showing an apparatus for fabricating a display device according to an embodiment of the present disclosure.

FIG. 12 is a plan view showing the apparatus for fabricating a display device according to the embodiment of the present disclosure.

FIG. 13 is a flowchart for illustrating a method for fabricating a display device according to an embodiment of the present disclosure.

FIG. 14 is a cross-sectional view showing a stage and a polarizing plate at step S100 of FIG. 13.

FIG. 15 is a view for illustrating data obtained by capturing the image of the polarizing plate and the stage at step S200 of FIG. 13.

FIG. 16 is a view for illustrating calculating position information of the polarizing plate relative to the stage from the data obtained by capturing the image of the polarizing plate and the stage at step S300 of FIG. 13.

FIG. 17 is a view for illustrating calculating position information of the polarizing plate relative to the stage from the data obtained by capturing the image of the polarizing plate and the stage at step S300 of FIG. 13.

FIG. 18 is a view showing an example of a pattern map of an adhesive member applied on the polarizing plate at step S400 of FIG. 13.

FIG. 19 is a view for illustrating data obtained by capturing the image of the polarizing plate and the stage at step S200 of FIG. 13.

FIG. 20 is a view for illustrating calculating position information of the polarizing plate relative to the stage from the data obtained by capturing the image of the polarizing plate and the stage at step S300 of FIG. 13.

FIG. 21 is a view for illustrating calculating position information of the polarizing plate relative to the stage from the data obtained by capturing the image of the polarizing plate and the stage at step S300 of FIG. 13.

FIG. 22 is a view showing an example of a pattern map of an adhesive member applied on the polarizing plate at step S400 of FIG. 13.

FIGS. 23A and 23B show an example of a pattern map created on a polarizing plate when there is no aligning unit in a conventional apparatus for fabricating a display device.

FIGS. 24A and 24B show an example of a pattern map created on a polarizing plate when there is no aligning unit in the apparatus for fabricating a display device according to the embodiment of the present disclosure.

FIG. 25 is a view showing an example of ejecting an adhesive member onto the polarizing plate in step S500 of FIG. 13.

FIG. 26 is a view showing an inkjet head.

FIG. 27 is a view showing an example of preliminarily curing an adhesive member applied on a polarizing plate by irradiating it with light.

FIG. 28 is a plan view showing an apparatus for fabricating a display device according to an embodiment of the present disclosure.

FIGS. 29A-29C are views showing an example of a pattern map created after alignment of a polarizing plate according to an embodiment.

FIG. 30 is an exploded, perspective view of a display device according to an embodiment of the present disclosure.

FIG. 31 is a block diagram of an electronic device according to an embodiment of the present disclosure.

FIG. 32 is a view showing electronic devices according to a variety of embodiments of the present disclosure.

### DETAILED DESCRIPTION

It is to be understood that the advantages and features of the subject matter, and the method of utilizing the living body, are described in detail below along with the attached technology. However, the present invention is not limited to other various forms of example resources, but only the present invention is provided to make the scope of the technology complete for those who can use the vast technology in various technical fields of the present invention, the technology is defined by the scope.

The opposite (elements) or layers "on" another location or layer includes all cases where it is directly on or overlaps another existence or intervenes another location. Likewise, the "under", "left" and "right" include all cases where it is directly jammed with another column or intervenes another layer or material. The same reference numerals designate the same elements throughout the specification.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. As used herein, the term “A/B” indicates only A, only B, or both A and B. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The following describes the identified contents.

Hereinafter, exemplary embodiments of the present disclosure will be described in detail with reference to the accompanying drawings.

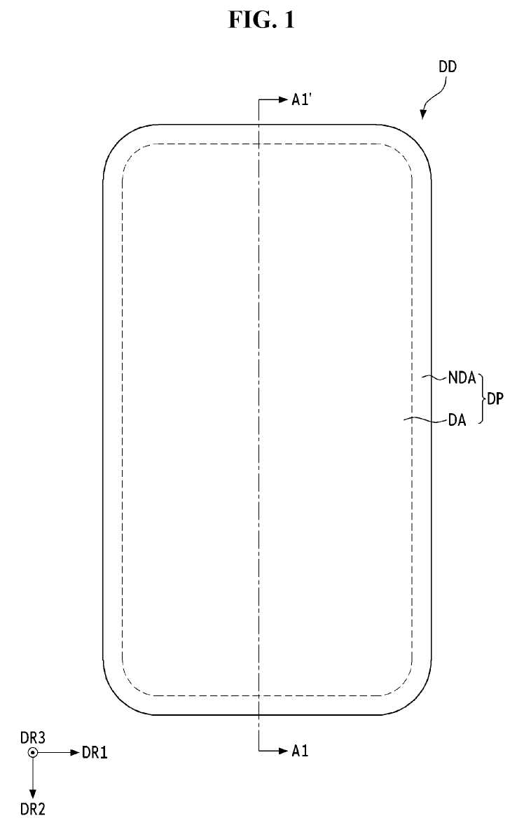

FIG. 1 is a plan view showing a display device according to an embodiment of the present disclosure.

Referring to FIG. 1, a display device DD according to an embodiment of the present disclosure is for displaying moving images or still images. The display device 10 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things (IoT) devices. The display device DD may be one of an organic light-emitting display device, a liquid-crystal display device, a plasma display device, a field emission display device, an electrophoretic display device, an electrowetting display device, a quantum dot light-emitting display device, a micro LED display device and the like. In the following description, an organic light-emitting display device is described as an example of the display device DD. It is, however, to be understood that the present disclosure is not limited thereto.

The display device DD may have a variety of shapes. For example, the display device DD may have a generally rectangular shape in the plane defined by a first direction DR1 and a second direction DR2. For example, the display device DD may include two first sides extended in the first direction DR1 and two second sides extended in the second direction DR2 in the plane. According to an embodiment of the present disclosure, the first sides may be shorter than the second sides, but the present disclosure is not limited thereto.

In the drawings, the first direction DR1 and the second direction DR2 intersect each other as the horizontal directions. For example, the first direction DR1 and the second direction DR2 may be perpendicular to each other. In addition, a third direction DR3 may intersect the first direction DR1 and the second direction DR2, and may be a vertical direction, for example. Herein, one sides in the first to third directions DR1, DR2 and DR3 may refer to the side indicated by the respective arrows, while the opposite sides in the first to third directions DR1, DR2 and DR3 may refer to the opposite sides of the sides indicated by the respective arrows. If only the first to third directions DR1, DR2 and DR3 are mentioned without distinguishing between one sides and the opposite sides in the first to third directions DR1, DR2 and DR3, they may encompass both the one sides and the opposite sides.

The display device DD may have sharp corners or rounded corners. For example, the corners where the first sides and the second sides of the display device DD meet each other may form a right angle or curved surfaces.

The shape of the display device DD when viewed from the top is not limited to that shown in the drawings. The shape of the display device DD may be modified to a circular shape, an oval shape, or other shapes. In addition, although the display surface of the display device DD including the display area DA is flat according to the embodiment of FIG. 1, the embodiments of the present disclosure are not limited thereto. For example, the display surface of the display device DD may include a curved surface at least partially.

The display device DD may include the display area DA, and a non-display area NDA around the display area DA.

The display area DA may include pixels for displaying images. In addition to the pixels, the display area DA may further include scan lines, data lines and power lines connected to the pixels.

The non-display area NDA may be located on at least one side of the display area DA and may partially or entirely surround the display area DA. Lines, pads, and/or at least one driver circuit electrically connected to the pixels in the display area DA may be arranged in the non-display area NDA.

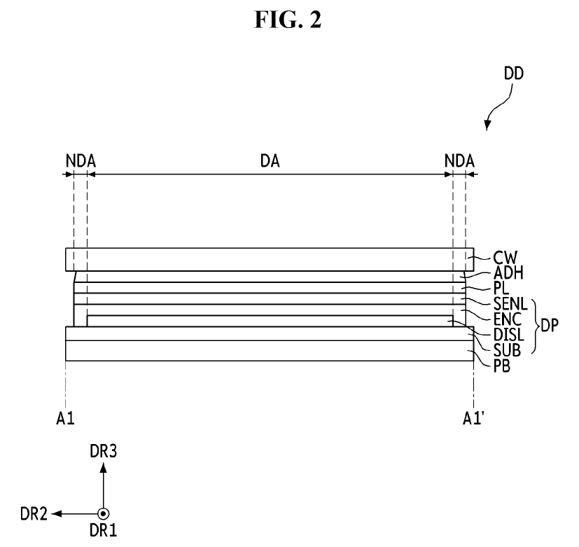

FIG. 2 is a cross-sectional view taken along line A1 – A1' of FIG. 1.

Referring to FIG. 2 in conjunction with FIG. 1, the display device 10 according to the embodiment may include a display panel DP, a polarizing film PL, an adhesive member ADH, a cover window CW, and a panel bottom cover PB. The display panel DP may include a substrate SUB, a display layer DISL, an encapsulation layer ENC, and a sensor electrode layer SENL.

The substrate SUB may include a transparent material. For example, the substrate SUB may include a transparent insulating material such as glass and quartz. The substrate SUB may be a rigid substrate. It is, however, to be understood that the substrate SUB is not limited thereto. The substrate SUB may include plastic such as polyimide (PI) and may have flexible characteristics so that it can be bent, folded or rolled.

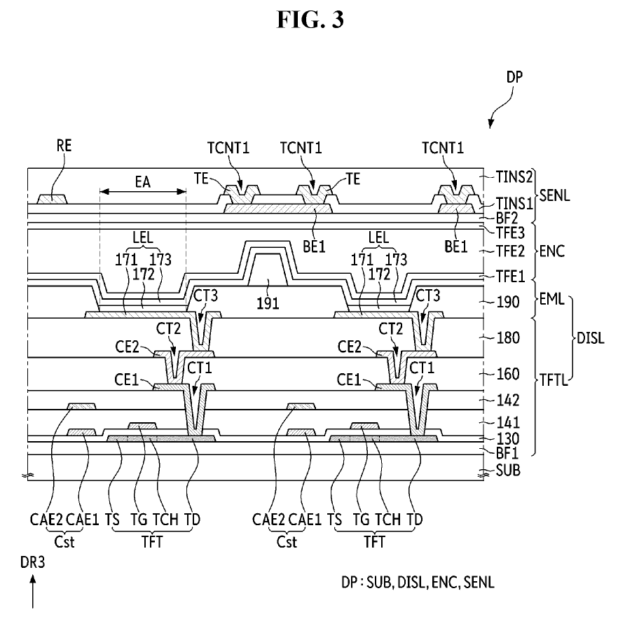

The display layer DISL may be located on a first surface of the substrate SUB. The display layer DISL may display images. The display layer DISL may include a thin-film transistor layer TFTL (see FIG. 3) in which thin-film transistors are formed, and an emission material layer EML (see FIG. 3) in which light-emitting elements that emit lights are arranged in the emission areas.

The display layer DISL may include scan lines, data lines, power lines, etc. for outputting light from emission areas in the display area DA. In the non-display area NDA, the display layer DISL may include a scan driver circuit outputting scan signals to the scan lines, fan-out lines connecting the data lines with the driver ICs.

The encapsulation layer ENC may encapsulate the emission material layer of the display layer DISL to prevent oxygen or moisture from permeating into the emission material layer of the display layer DISL. The encapsulation layer ENC may be located on the display layer DISL. The encapsulation layer ENC may be located on the upper and side surfaces of the display layer DISL. The encapsulation layer ENC may cover the display layer DISL.

The sensor electrode layer SENL may be located on the display layer DISL. The sensor electrode layer SENL may include sensor electrodes. The sensor electrode layer SENL can sense a user's touch using the sensor electrodes.

The polarizing film PL may be placed on the sensor electrode layer SENL. The polarizing film PL may be located on the display panel DP in order to reduce reflection of external light. The polarizing film PL may include a first base member, a linear polarizer, a retardation film such as a λ/4 (quarter-wave) plate, and a second base member. The first base member, the retardation film, the linear polarizer and the second base member of the polarizing film PL may be sequentially stacked on the display panel DP.

The cover window CW may be located on the polarizing film PL. The cover window CW may be transparent so that light generated in the display panel DP can be transmitted. The cover window CW may include glass or plastic material. In some embodiments where the cover window CW includes glass, it may include chemically strengthened glass by ion substitution. According to another embodiment where the cover window CW includes plastic, it may include a polyimide (PI) film.

The cover window CW may be attached to the polarizing film PF by an adhesive member ADH. The adhesive member ADH may include one of a pressure sensitive adhesive (PSA), an optical clear adhesive (OCA), and an optical clear resin (OCR).

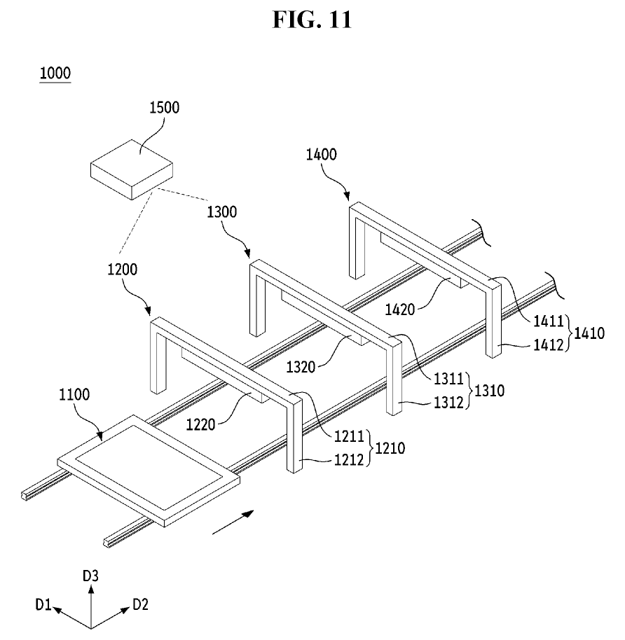

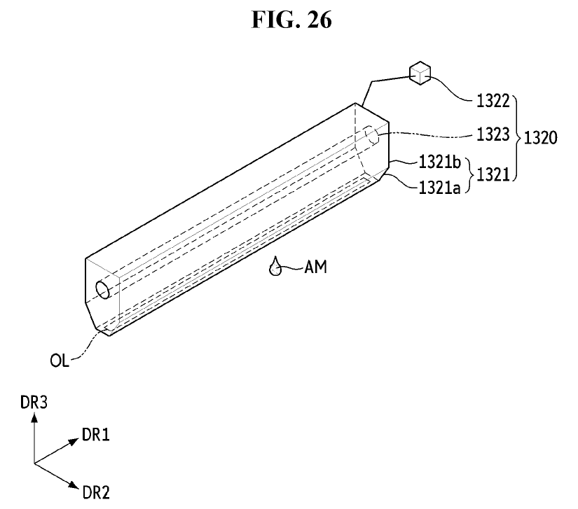

According to the embodiment, the adhesive member ADH may be formed by applying a liquid adhesive material AM (see FIG. 26) using an apparatus 1000 for fabricating a display device described below (see FIG. 11) and then curing it.

The panel bottom cover PB may be located on a second surface of the substrate SUB of the display panel DP. The second surface of the substrate SUB may be opposite to the first surface. The panel bottom cover PB may be attached to the second surface of the substrate SUB of the display panel DP through an adhesive member such as a pressure sensitive adhesive (PSA).

The panel bottom cover PB may include at least one of: a light-blocking member for absorbing light incident from outside, a buffer member for absorbing external impact, and a heat dissipating member for efficiently discharging heat from the display panel DP.

An apparatus 1000 and a method for fabricating a display device for forming an adhesive member ADH will be described later.

FIG. 3 is a cross-sectional view showing an example of a display panel according to an embodiment of the present disclosure.

Referring to FIG. 3, according to some embodiments, the display panel DP may be an organic light-emitting display panel including light-emitting elements LEL each including an organic emissive layer 172. The display panel DP may include a substrate SUB, a display layer DISL, an encapsulation layer ENC, and a sensor electrode layer SENL. The display layer DISL may include a thin-film transistor layer TFTL including a plurality of thin-film transistors and an emission material layer EML including a plurality of light-emitting elements.

The substrate SUB may include a transparent material. For example, the substrate SUB may include a transparent insulating material such as glass and quartz. The substrate SUB may be a rigid substrate. It is, however, to be understood that the substrate SUB is not limited thereto. The substrate SUB may include plastic such as polyimide (PI) and may have flexible characteristics so that it can be bent, folded or rolled.

The display layer DISL may include a thin-film transistor layer TFTL including a plurality of thin-film transistors and an emission material layer EML including a plurality of light-emitting elements.

The thin-film transistor layer TFTL may include a first buffer film BF1, a thin-film transistor TFT, a gate insulator 130, a first interlayer dielectric layer 141, a capacitor Cst, a second interlayer dielectric layer 142, a first data metal layer, a first organic film 160, a second data metal layer, and a second organic film 180.

The first buffer film BF1 may be located on the substrate SUB. The first buffer film BF1 may be formed of an inorganic material such as a silicon nitride layer, a silicon oxynitride layer, a silicon oxide layer, a titanium oxide layer, and an aluminum oxide layer. Alternatively, the first buffer film BF1 may be made up of multiple layers in which two or more of a silicon nitride layer, a silicon oxynitride layer, a silicon oxide layer, a titanium oxide layer and an aluminum oxide layer are stacked on one another.

An active layer including a channel region TCH, a source region TS and a drain region TD of the thin-film transistor TFT may be located on the first buffer film BF1. The active layer may be made of polycrystalline silicon, monocrystalline, low-temperature polycrystalline silicon, amorphous silicon, or an oxide semiconductor. When the active layer includes polycrystalline silicon or an oxide semiconductor material, the source region TS and the drain region TD in the active layer may be conductive regions doped with ions or impurities to have conductivity.

The gate insulator 130 may be disposed on the active layer of the thin-film transistor TFT. The gate insulator 130 may include an inorganic layer, for example, a silicon nitride layer, a silicon oxynitride layer, a silicon oxide layer, a titanium oxide layer, or an aluminum oxide layer.

A first gate metal layer including a gate electrode TG of the thin-film transistor TFT, a first capacitor electrode CAE1 of a capacitor Cst, and scan lines may be disposed on the gate insulator 130. The gate electrode G of the thin-film transistor TFT may overlap the channel region TCH in the third direction (z-axis direction). The first gate metal layer may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first interlayer dielectric layer 141 may be located on the first gate metal layer. The first interlayer dielectric layer 141 may include an inorganic layer, for example, a silicon nitride layer, a silicon oxynitride layer, a silicon oxide layer, a titanium oxide layer, or an aluminum oxide layer. The first interlayer dielectric layer 141 may include a number of inorganic films.

The second gate metal layer including a second capacitor electrode CAE2 of the capacitor Cst may be located on the first interlayer dielectric layer 141. The second capacitor electrode CAE2 may overlap the first capacitor electrode CAE1 in the third direction (z-axis direction). Therefore, the capacitor Cst may be formed by the first capacitor electrode CAE1, the second capacitor electrode CAE2, and an inorganic insulating dielectric film located between the electrodes and serving as a dielectric film. The second gate metal layer may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A second interlayer dielectric layer 142 may be located on the second gate metal layer. The second interlayer dielectric layer 142 may include an inorganic layer, for example, a silicon nitride layer, a silicon oxynitride layer, a silicon oxide layer, a titanium oxide layer, or an aluminum oxide layer. The second interlayer dielectric layer 142 may include a number of inorganic films.

The first data metal layer including first connection electrodes CE1 and data lines may be disposed on the second interlayer dielectric layer 142. The first connection electrode CE1 may be connected to the drain region TD through a first contact hole CT1 penetrating the gate insulator 130, the first interlayer dielectric layer 141 and the second interlayer dielectric layer 142. The first data metal layer may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A first organic film 160 may be disposed over the first connection electrode CE1 for providing a flat surface over the thin-film transistors TFT having uneven heights. The first organic film 160 may be formed as an organic layer such as an acryl resin, an epoxy resin, a phenolic resin, a polyamide resin and a polyimide resin.

A second data metal layer including second connection electrodes CE2 may be located on the first organic film 160. The second data metal layer may be connected to the first connection electrode CE1 through a second contact hole CT2 penetrating the first organic film 160. The second data metal layer may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second organic film 180 may be located on the second connection electrode CE2. The second organic film 180 may be formed as an organic layer such as an acryl resin, an epoxy resin, a phenolic resin, a polyamide resin and a polyimide resin.

It should be noted that the second data metal layer including the second connection electrodes CE2 and the second organic film 180 may be eliminated.

The emission material layer EML is located on the thin-film transistor layer TFTL. The emission material layer EML may include light-emitting elements LEL and a pixel-defining layer 190.

Each of the light-emitting elements LEL may include a pixel electrode 171, an emissive layer 172, and a common electrode 173. In each of the emission areas EA, the pixel electrode 171, the emissive layer 172 and the common electrode 173 are stacked on one another sequentially, so that holes from the pixel electrode 171 and electrons from the common electrode 173 are combined with each other in the emissive layer 172 to emit light. In such case, the pixel electrode 171 may be an anode electrode while the common electrode 173 may be a cathode electrode.

A pixel electrode layer including the pixel electrode 171 may be formed on the second organic film 180. The pixel electrode 171 may be connected to the second connection electrode CE2 through a third contact hole CT3 penetrating the second organic film 180. The pixel electrode layer may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

In the top-emission structure where light exits from the emissive layer 172 toward the common electrode 173, the pixel electrode 171 may be made up of a single layer of molybdenum (Mo), titanium (Ti), copper (Cu) or aluminum (Al), or may be made up of a stack structure of aluminum and titanium (Ti/Al/Ti), a stack structure of aluminum and ITO (ITO/Al/ITO), an APC alloy and a stack structure of APC alloy and ITO (ITO/APC/ITO) in order to increase the reflectivity. The APC alloy is an alloy of silver (Ag), palladium (Pd) and copper (Cu).

The pixel-defining layer 190 may define the emission areas EA of the pixels. To this end, the pixel-defining layer 190 may be formed on the second organic film 180 to expose a part of the pixel electrode 171. The pixel-defining layer 190 may cover edges of the pixel electrodes 171. The pixel-defining layer 190 may be located inside the third contact hole CT3. In other words, the third contact hole CT3 may be filled with the pixel-defining layer 190. The pixel-defining layer 190 may be formed of an organic layer such as an acryl resin, an epoxy resin, a phenolic resin, a polyamide resin and a polyimide resin.

A spacer 191 may be disposed on the pixel-defining layer 190. The spacer 191 may support a mask during a process of fabricating the emissive layer 172. The spacer 191 may be implemented as an organic layer such as an acryl resin, an epoxy resin, a phenolic resin, a polyamide resin and a polyimide resin.

The emissive layer 172 is formed on the pixel electrode 171. The emissive layer 172 may include an organic material to emit light of a particular color. For example, the emissive layer 172 may include a hole transporting layer, an organic material layer, and an electron transporting layer. The organic material layer may include a host and a dopant. The organic material layer may include a material that emits a predetermined light, and may be formed using a phosphor or a fluorescent material.

The common electrode 173 is formed on the emissive layer 172. The common electrode 173 may be formed to cover the emissive layer 172. The common electrode 173 may be a common layer formed across the emission areas EA. A capping layer may be formed on the common electrode 173.

In the top-emission structure, the common electrode 173 may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the common electrode 173 is made of a semi-transmissive metal material, the light extraction efficiency can be increased by using microcavities.

The encapsulation layer ENC may be disposed on the emission material layer EML. The encapsulation layer ENC may include one or more inorganic films TFE1 and TFE3 to prevent permeation of oxygen or moisture into the emission material layer EML. In addition, the encapsulation layer ENC may include at least one organic film in order to protect the emission material layer EML from particles such as dust. For example, the encapsulation layer ENC may include a first inorganic encapsulation film TFE1, an organic encapsulation film TFE2 and a second inorganic encapsulation film TFE3.

The first inorganic encapsulation film TFE1 may be located on the common electrode 173, the organic encapsulation film TFE2 may be located on the first inorganic encapsulation film TFE1, and the second inorganic encapsulation film TFE3 may be located on the organic encapsulation film TFE2. The first inorganic encapsulation film TFE1 and the second inorganic encapsulation film TFE3 may be made up of multiple layers in which one or more inorganic layers of a silicon nitride layer, a silicon oxynitride layer, a silicon oxide layer, a titanium oxide layer and an aluminum oxide layer are alternately stacked on one another. The organic encapsulation film TFE2 may be an organic film such as an acryl resin, an epoxy resin, a phenolic resin, a polyamide resin, a polyimide resin, etc.

The sensor electrode layer SENL may be located on the encapsulation layer ENC. The sensor electrode layer SENL may include a second buffer film BF2, a first bridge BE1, a first sensor insulating layer TINS1, sensor electrodes TE and RE, and a second sensor insulating layer TINS2.

A second buffer film BF2 may be located on the encapsulation layer ENC. The second buffer film BF2 may include at least one inorganic film. For example, the second buffer film BF2 may be made up of multiple layers in which one or more inorganic layers of a silicon nitride layer, a silicon oxynitride layer, a silicon oxide layer, a titanium oxide layer and an aluminum oxide layer are alternately stacked on one another. The second buffer film BF2 may be eliminated.

First bridge electrodes BE1 may be located on the second buffer film BF2. The first bridge electrodes BE1 may be made up of a single layer of molybdenum (Mo), titanium (Ti), copper (Cu) or aluminum (Al), or may be made up of a stack structure of aluminum and titanium (Ti/Al/Ti), a stack structure of aluminum and ITO (ITO/Al/ITO), an APC alloy and a stack structure of an APC alloy and ITO (ITO/APC/ITO).

A first sensor insulating layer TINS1 may be located on the first bridge electrodes BE1. The first sensor insulating layer TINS1 may be formed of an inorganic layer, for example, a silicon nitride layer, a silicon oxynitride layer, a silicon oxide layer, a titanium oxide layer, or an aluminum oxide layer.

The sensor electrodes, i.e., driving electrodes TE and sensing electrodes RE may be arranged on the first sensor insulating layer TINS1. In addition, dummy patterns may be arranged on the first sensor insulating layer TNIS1. The driving electrodes TE, the sensing electrodes RE and the dummy patterns do not overlap the emission areas EA. The driving electrodes TE, the sensing electrodes RE and the dummy patterns may be made up of a single layer of molybdenum (Mo), titanium (Ti), copper (Cu) or aluminum (Al), or may be made up of a stack structure of aluminum and titanium (Ti/Al/Ti), a stack structure of aluminum and ITO (ITO/Al/ITO), an APC alloy and a stack structure of an APC alloy and ITO (ITO/APC/ITO).

The second sensor insulating layer TINS2 may be disposed on the driving electrodes TE, the sensing electrodes RE, and the dummy patterns. The second sensor insulating layer TINS2 may include at least one of an inorganic film and an organic film. The inorganic film may be a silicon nitride layer, a silicon oxynitride layer, a silicon oxide layer, a titanium oxide layer, or an aluminum oxide layer. The organic film may be an acryl resin, an epoxy resin, a phenolic resin, a polyamide resin and a polyimide resin.

Hereinafter, an apparatus and a method for fabricating a display device according to an embodiment of the present disclosure will be described. In the following description, the same or similar elements will be denoted by the same or similar reference numerals, and redundant descriptions will be omitted or briefly described.

Previously, a conventional apparatus for fabricating a display device had a fixed pattern map for ejecting ink onto a substrate. While the substrate is fabricated based on a given drawing, the substrate may be slightly smaller or larger compared to the drawing depending on the fabrication tolerance. If the substrate is fabricated slightly smaller compared to the drawing, the ink ejected based on the fixed pattern map may flow over the substrate. If the substrate is fabricated slightly larger compared to the drawing, the ink ejected based on the fixed pattern map may fail to cover the entire substrate.

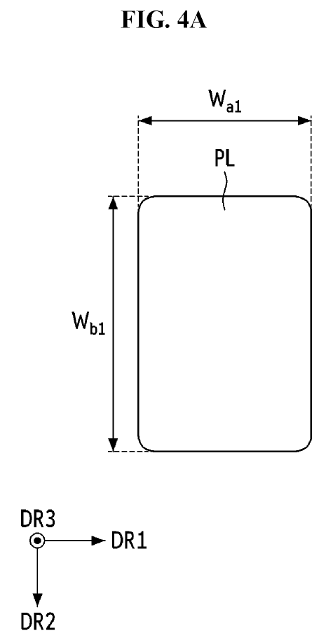

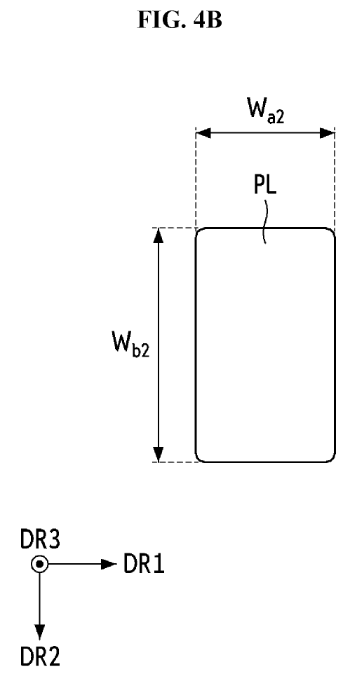

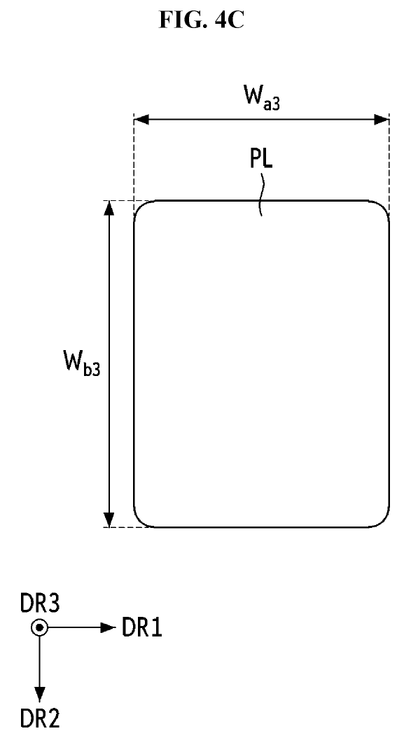

FIGS. 4A-4C are plan views showing examples of polarizing plates of different sizes according to an embodiment.

FIG. 4A shows a polarizing plate PL fabricated according to specifications in the drawing, FIG. 4B shows a polarizing plate PL fabricated smaller than the specifications in the drawing, and FIG. 4C shows a polarizing plate PL fabricated larger than the specifications in the drawing. In FIG. 4A, Wₐ₁ denotes the length of a side of the polarizing plate PL which is extended in the first direction DR1, and W_{b1} denotes the length of a side of the polarizing plate PL which is extended in the second direction DR2. In FIG. 4B, Wₐ₂ denotes the length of a side of the polarizing plate PL which is extended in the first direction DR1, and W_{b2} denotes the length of a side of the polarizing plate PL which is extended in the second direction DR2. In FIG. 4C, Wₐ₃ denotes the length of a side of the polarizing plate PL which is extended in the first direction DR1, and W_{b3} denotes the length of a side of the polarizing plate PL which is extended in the second direction DR2. In FIG. 4, the lengths of the sides of the polarizing plate PL which are extended in the first direction DR1 may have the following relationship: Wₐ₂ < Wₐ₁ < Wₐ₃. In FIGS. 4A-4C, the lengths of the sides of the polarizing plate PL which are extended in the second direction DR2 may have the following relationship: W_{b2} < W_{b1} < W_{b3}.

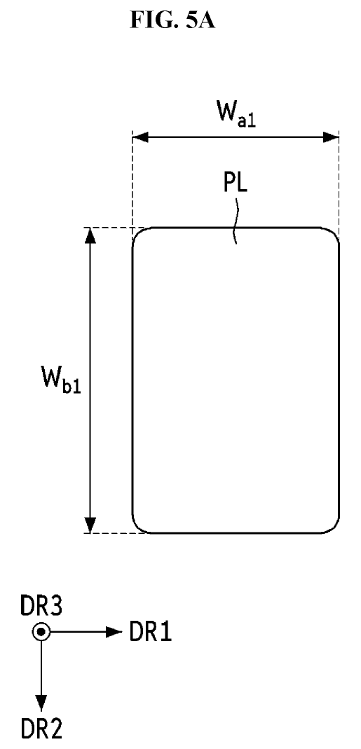

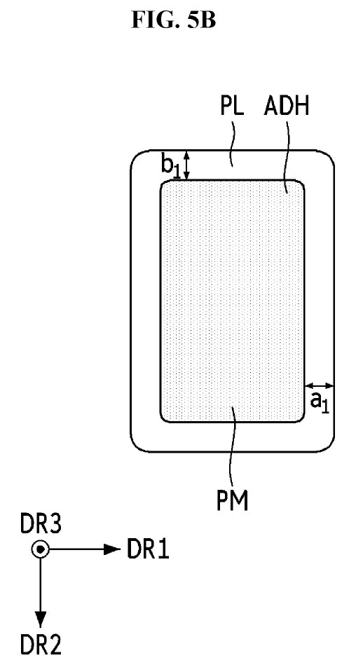

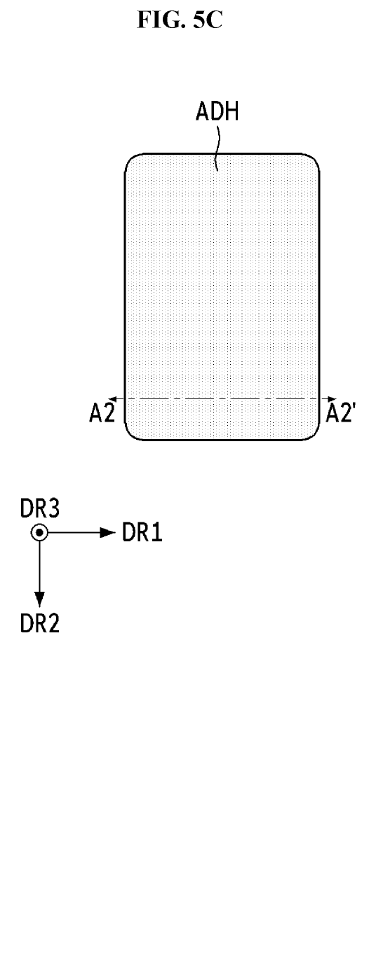

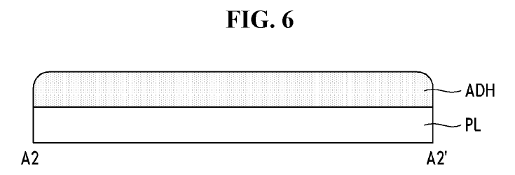

FIGS. 5A-5C are views showing the polarizing plate of FIG. 4A and an adhesive member applied on the polarizing plate. FIG. 6 is a cross-sectional view taken along line A2 – A2' of FIG. 5C.

FIG. 5A shows a polarizing plate PL fabricated according to the specifications in the given drawing. FIG. 5B shows an adhesive member ADH applied on the polarizing plate PL fabricated according to the specifications in the drawing by using a designed pattern map PM. The designed pattern map PM may be smaller than the polarizing plate PL by an offset. The offset may be determined in consideration of how far the adhesive member ADH may spread on the polarizing plate PL depending on the fluidity of the adhesive member ADH. In FIG. 5B, the offset may include a₁ and b₁. FIG. 5C is a view showing the adhesive member ADH applied on the polarizing plate PL when it spreads naturally.

Referring to FIG. 6, when an adhesive member ADH is applied by using the designed pattern map PM on the polarizing plate PL fabricated according to the given drawing specifications, it can be seen that the adhesive member ADH is applied evenly on the polarizing plate PL.

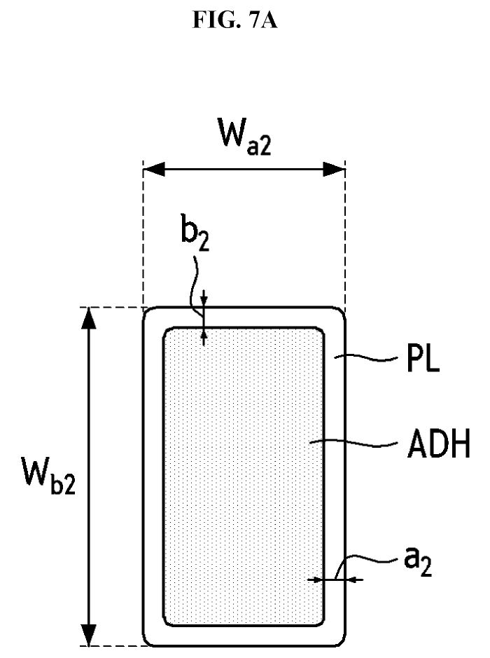

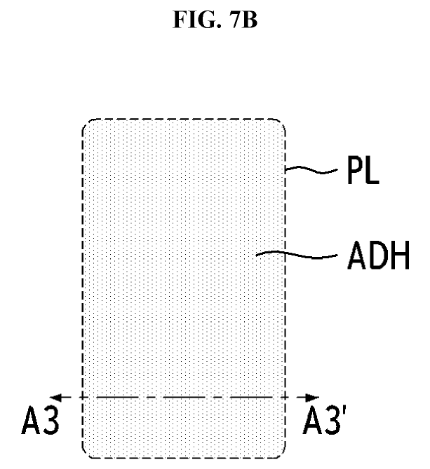

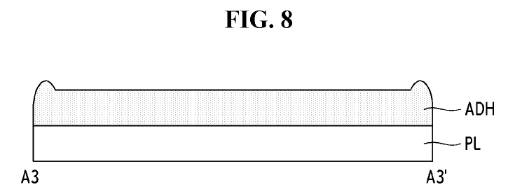

FIGS. 7A and 7B are views showing the polarizing plate of FIG. 4B and an adhesive member applied on the polarizing plate. FIG. 8 is a cross-sectional view taken along line A3 – A3' of FIG. 7B.

FIG. 7A shows an adhesive member ADH applied on the polarizing plate PL fabricated smaller than the specifications in the drawing by using a designed pattern map PM. In FIG. 7A, the offset may include a₂ and b₂. In FIG. 7A, with the same designed pattern map PM, the polarizing plate PL has been fabricated smaller than the specifications in the drawing, and thus the offset may be less. Herein, the offset a2 may be less than a1, and b2 may be less than b1. FIG. 7B is a view showing the adhesive member ADH applied on the polarizing plate PL when it spreads naturally.

Referring to FIG. 8, when an adhesive member ADH is applied by using the designed pattern map PM on the polarizing plate PL fabricated smaller than the specifications in the drawing, the adhesive member ADH may accumulate on the edges of the polarizing plate PL. This may be because excessive adhesive member ADH was applied for the size of the polarizing plate PL.

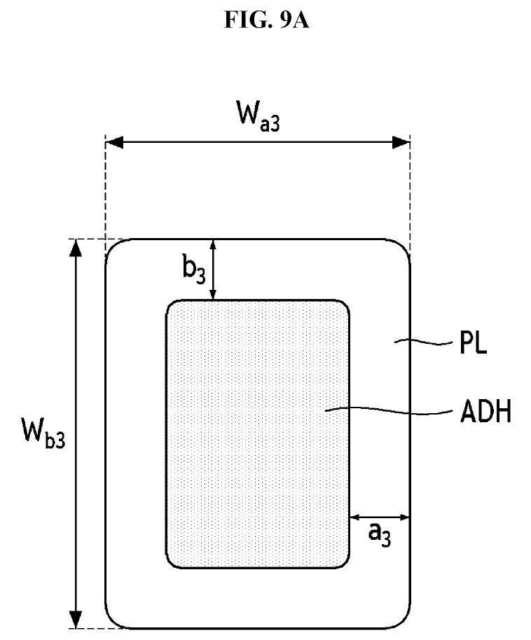

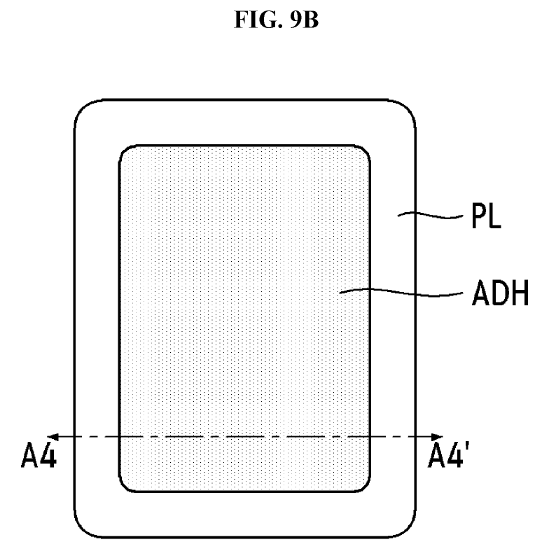

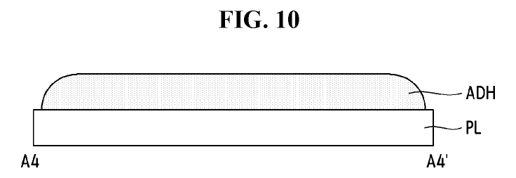

FIGS. 9A and 9B are views showing the polarizing plate of FIG. 4C and an adhesive member applied on the polarizing plate. FIG. 10 is a cross-sectional view taken along line A4 - A4' of FIG. 9B.

FIG. 9A shows an adhesive member ADH applied by using the designed pattern map PM on the polarizing plate PL fabricated larger than the specifications in the drawing. In FIG. 9A, the offset may includea₃ and b₃. In FIG. 9A, with the same designed pattern map PM, the polarizing plate PL has been fabricated larger than the specifications in the drawing, and thus the offset may be larger. The offset a3 may be larger than a1, and b3 may be larger than b1. FIG. 9B is a view showing the adhesive member ADH applied on the polarizing plate PL when it spreads naturally.

Referring to FIG. 10, when the adhesive member ADH is applied by using the designed pattern map PM on the polarizing plate PL fabricated larger than the specifications in the drawing, the adhesive member ADH may not sufficiently spread to the edges of the polarizing plate PL. This may be because less adhesive member ADH was applied for the size of the polarizing plate PL.

The apparatus 1000 for fabricating a display device of the present disclosure may create a pattern map PM based on the size of the substrate SUB and the position information of the substrate SUB relative to the stage 1100 and may eject an appropriate amount of ink onto the substrate SUB to fit for the size of the substrate SUB. Because the pattern map PM created according to the actual size of the substrate SUB is used rather than the initially set pattern map PM, it is possible to prevent the ink from being ejected onto the substrate SUB overly or insufficiently.

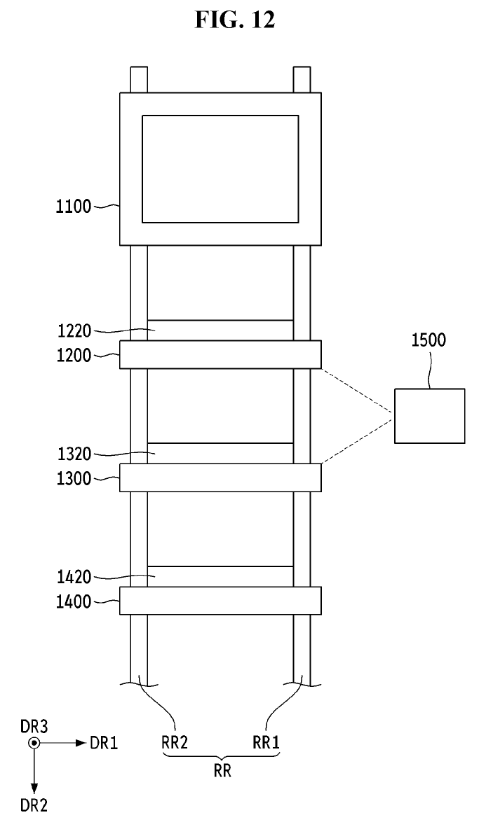

FIG. 11 is a perspective view showing an apparatus for fabricating a display device according to an embodiment of the present disclosure. FIG. 12 is a plan view showing the apparatus for fabricating a display device according to the embodiment of the present disclosure.

Referring to FIGS. 11 and 12, an apparatus 1000 for fabricating a display device according to an embodiment may include a stage 1100, a sensor unit 1200, an inkjet head unit 1300, a light irradiating unit 1400, a pattern generating unit 1500, and a moving unit RR.

The stage 1100 may provide a space where a substrate SUB is placed. The substrate SUB may be placed on the stage 1100 while a printing process is carried out. The overall shape of the stage 1100 may follow the shape of the substrate SUB when viewed from the top. For example, if the substrate SUB is in a rectangular shape, the overall shape of the stage 1100 may be rectangular. If the substrate SUB is in a circular shape, the overall shape of the stage 1100 may be circular.

The stage 1100 may include a first alignment mark AM1 and a second alignment mark AM2. The first alignment mark AM1 may include a first sub-mark SM1 extended in the first direction DR1, and a second sub-mark SM2 extended in the second direction DR2 intersecting the first direction DR1. The second alignment mark AM2 may include a third sub-mark SM3 extended in the first direction DR1, and a fourth sub-mark SM4 extended in the second direction DR2 intersecting the first direction DR1.

The first alignment mark AM1 and the second alignment mark AM2 may be fixed on the stage 1100. When the substrate SUB is placed on the stage 1100, position information of the substrate SUB relative to the stage 1100 may be calculated based on the distance and angle from the substrate SUB to the first alignment mark AM1 and the second alignment mark AM2.

The sensor unit 1200 may obtain data by capturing the image of the stage 1100 on which the substrate SUB is placed and/or measuring numerical values. The sensor unit 1200 may include a sensor 1220. The sensor 1220 may include at least one of a line scan camera, a vision camera, and a laser camera. The sensor unit 1200 may include a first support 1210 that may support the sensor 1220. The first support 1210 may include a first horizontal support 1211 and first vertical supports 1212.

A line scan camera may capture the image of the stage 1100 on which the substrate SUB is placed so as to acquire the edges of the substrate SUB as a line image. The lengths of the edges of the substrate SUB may be checked from the line image. For example, if the substrate SUB is in a rectangular shape, the length of the longer sides and the length of the shorter sides of the substrate SUB may be checked. If the substrate SUB is in a circular shape, the arc of the substrate SUB may be checked. If the substrate SUB has a rectangular shape with rounded corners, the shortest length between two opposing surfaces may be defined as the length of a side.

The pattern generating unit 1500 may receive data from the sensor unit 1200 and may calculate information on the size of the substrate SUB and the position of the substrate SUB relative to the stage 1100. The pattern generating unit 1500 may generate a pattern map PM based on the size and position information of the substrate SUB. The pattern generating unit 1500 may be connected to the sensor unit 1200 and/or the inkjet head unit 1300 wired or wirelessly. The pattern generating unit 1500 may receive data from the sensor unit 1200 to create a pattern map PM based on the size and position information of the substrate SUB, and may transmit the pattern map PM information to the inkjet head unit 1300.

The inkjet head unit 1300 may include at least one inkjet head 1320 that receives the pattern map PM information from the pattern generating unit 1500 to eject ink onto the substrate SUB. The inkjet head unit 1300 may include a second support 1310 that may support the inkjet head 1320. The second support 1310 may include a second horizontal support 1311 and second vertical supports 1312.

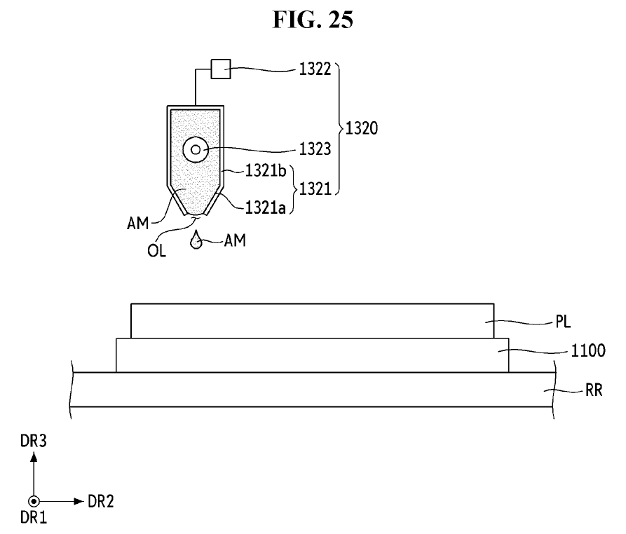

The inkjet head 1320 may eject the ink. The inkjet head 1320 may apply the ink onto the substrate SUB fixed on the stage 1100. The inkjet head 1320 may include a body part 1321, an ejection driver 1322, and a stirring part 1323 (see FIG. 25).

The light irradiating unit 1400 may irradiate light onto the ink applied on the substrate SUB to preliminarily cure it. The ink may contain a material that can be cured by light. The light irradiating unit 1400 may include a light source 1420. The light source 1420 may irradiate an ultraviolet light. The light irradiating unit 1400 may include a third support 1410 that may support the light source 1420. The third support 1410 may include a third horizontal support 1411 and third vertical supports 1412.

The light source 1420 may have a shape that is extended in the first direction DR1. The light irradiated by the light source 1420 may be in the form of a linear light extended in the first direction DR1. It should be understood, however, that the embodiments of the present disclosure are not limited thereto. The light irradiated by the light source 1420 may be in the form of a surface light that is extended in the first direction DR1 and has a width in the second direction DR2.

The moving unit RR may include a first rail RR1 and a second rail RR2 extended in the second direction DR2. The stage 1100 may be placed on the moving unit RR. The moving unit RR may reciprocally move the stage 1100 along the moving unit RR in the second direction DR2. The stage 1100 may perform a printing process on the entire area of the substrate SUB while moving in the second direction DR2.

Hereinafter, a method for driving the apparatus 1000 for fabricating a display device will be described in detail with reference to a method for fabricating a display device.

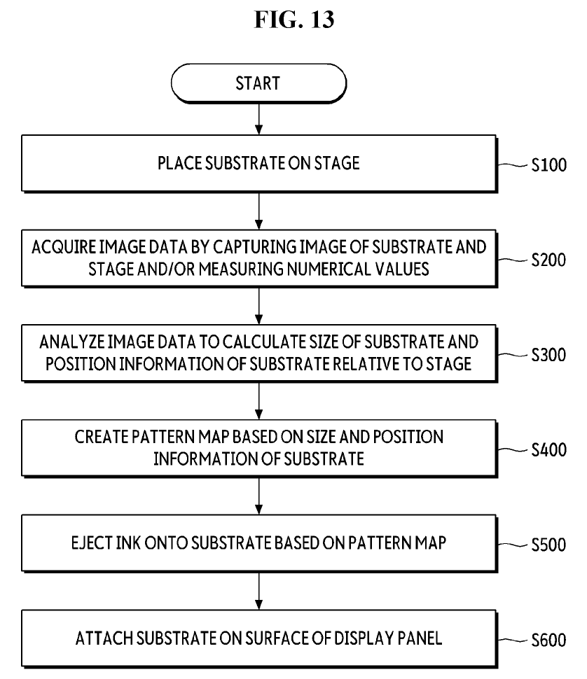

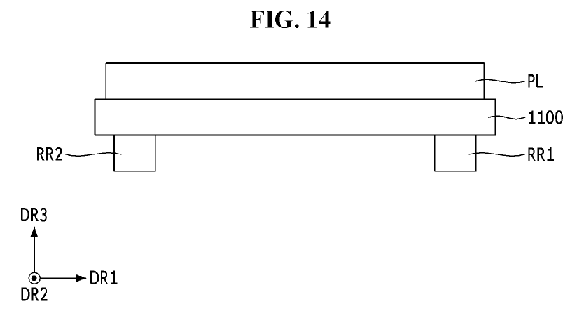

FIG. 13 is a flowchart for illustrating a method for fabricating a display device according to an embodiment of the present disclosure. FIG. 14 is a cross-sectional view showing a stage and a polarizing plate at step S100 of FIG. 13.

Initially, a substrate SUB may be placed on a stage 1100 (step S100). Herein, a polarizing plate PL may be used as the substrate SUB. Although the polarizing plate PL is described as the substrate SUB herein, the present disclosure is not limited thereto. Any of a variety of substrates may be used as long as it can be used in a process of applying ink onto the substrate.

Referring to FIG. 14, it can be seen that the polarizing plate PL is placed on the stage 1100 on the first rail RR1 and the second rail RR2.

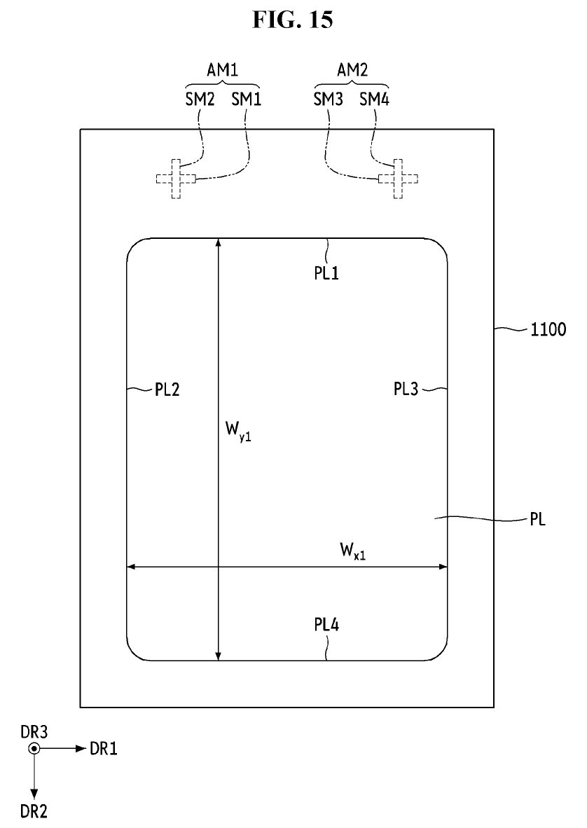

FIGS. 15-18 show a first embodiment where the size of a polarizing plate PL and the position of the polarizing plate PL relative to the stage 1100 are calculated to create a pattern map, with the polarizing plate PL aligned on the stage 1100.

FIG. 15 is a view for illustrating data obtained by capturing the image of the polarizing plate and the stage at step S200 of FIG. 13.

Subsequently, data may be obtained by capturing the image of the polarizing plate PL and the stage 1100 and/or measuring numerical values (step S200). Referring to FIG. 15, if a line scanner camera is used as the sensor 1220, a line image in which the edges of the polarizing plate PL are drawn on the stage 1100 may be acquired. As shown in FIG. 15, the length of the polarizing plate PL in the first direction DR1 is Wx1, which is the shortest distance from a second side PL2 to a third side PL3 of the polarizing plate PL. The length in the second direction DR2 is Wy1, which is the shortest distance from a first side PL1 to a fourth side PL4 of the polarizing plate PL.

Subsequently, by analyzing the image data (line image), the size of the polarizing plate PL and the position information of the polarizing plate PL relative to the stage 1100 may be calculated (step S300).

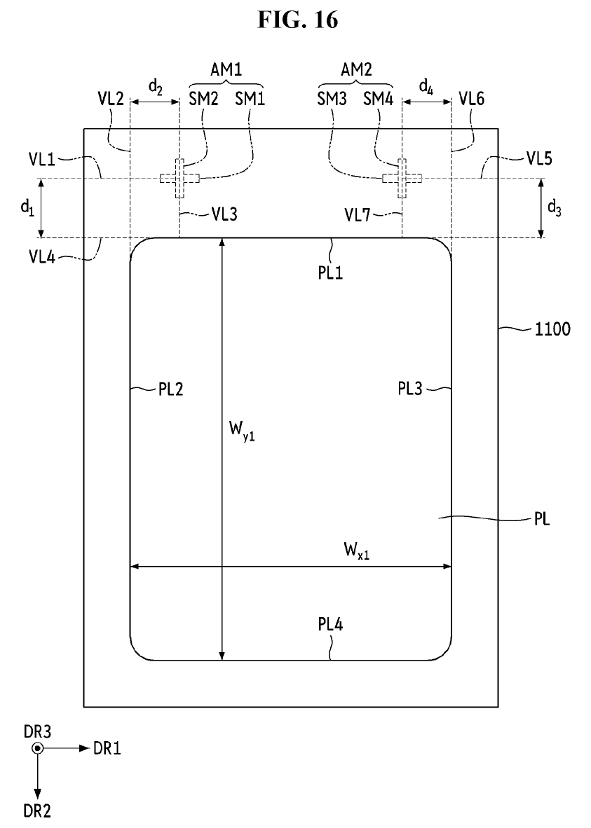

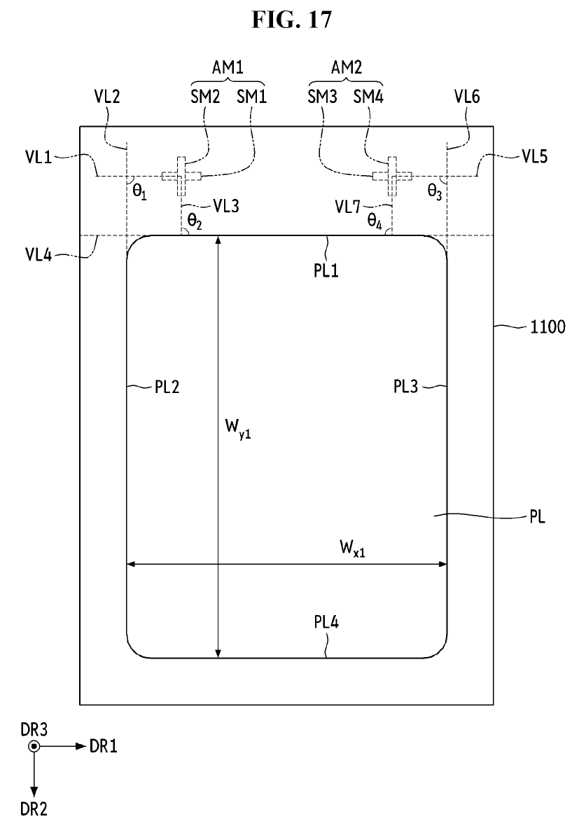

FIG. 16 is a view for illustrating calculating position information of the polarizing plate relative to the stage from the data obtained by capturing the image of the polarizing plate and the stage at step S300 of FIG. 13. FIG. 17 is a view for illustrating calculating position information of the polarizing plate relative to the stage from the data obtained by capturing the image of the polarizing plate and the stage at step S300 of FIG. 13.

Referring to FIG. 16, the pattern generating unit 1500 may measure a first distance d₁ between the first sub-mark SM1 and the first side PL1 of the line image, and a second distance d₂ between the second sub-mark SM2 and the second side PL2 of the line image. In addition, the pattern generating unit 1500 may measure a third distance d₃ between the third sub-mark SM3 and the first side PL1 of the line image and a fourth distance d4 between the fourth sub-mark SM4 and the third side PL3 of the line image. In an embodiment, the first distance d₁ in the second direction DR2 may be a distance from the center of the first sub-mark SM1 to a point where a third virtual line VL3 extended from the center of the first sub-mark SM1 in the second direction DR2 and a fourth virtual line VL4 extended from the first side PL1 of the line image cross each other, the second distance d₂ in the first direction DR1 may be a distance from the center of the second sub-mark SM2 to a point where a first virtual line VL1 extended from the center of the first sub-mark SM1 in the first direction DR1 and a second virtual line VL2 extended from the second side PL2 of the line image cross each other, the third distance d₃ in the second direction DR2 may be a distance from the center of the third sub-mark SM3 to a point where a seventh virtual line VL7 extended from the center of the third sub-mark SM3 in the second direction DR2 and the fourth virtual line VL4 extended from the first side PL1 of the line image cross each other, and the fourth distance d₄ in the first direction DR1 may be a distance from the center of the fourth sub-mark SM4 to a point where a fifth virtual line VL5 extended from the center of the fourth sub-mark SM4 in the first direction DR1 and a sixth virtual line VL6 extended from the third side PL3 of the line image cross each other. Here, the center of the first sub-mark SM1 and the center of the second sub-mark SM2 are the same, and the center of the third sub-mark SM3 and the center of the fourth sub-mark SM4 are the same.

Referring to FIG. 17, the pattern generating unit 1500 may measure a first angle θ₁ formed by the first virtual line VL1 extended from the center of the first sub-mark SM1 in the first direction DR1 and the second virtual line VL2 extended from the second side PL2 of the line image, and a second angle θ₂ formed by the third virtual line VL3 extended from the center of the second sub-mark SM2 in the second direction DR2 and the fourth virtual line VL4 extended from the first side PL1 of the line image. The pattern generating unit 1500 may measure a third angle θ₃ formed by the fifth virtual line VL5 extended from the center of the third sub-mark SM3 in the first direction DR1 and the sixth virtual line VL6 extended from the third side PL3 of the line image, and a fourth angle θ₄ formed by the seventh virtual line VL7 extended from the center of the fourth sub-mark SM4 in the second direction DR2 and the fourth virtual line VL4 extended from the first side PL1 of the line image.

The pattern generating unit 1500 may calculate position information of the polarizing plate PL relative to the stage 1100 based on the first distance d1, the second distance d2, the third distance d3, the fourth distance d4, the first angle θ₁, the second angle θ₂, the third angle θ₃, and the fourth angle θ₄.

Subsequently, a pattern map PM may be created based on the size of the polarizing plate PL and the position information (step S400).

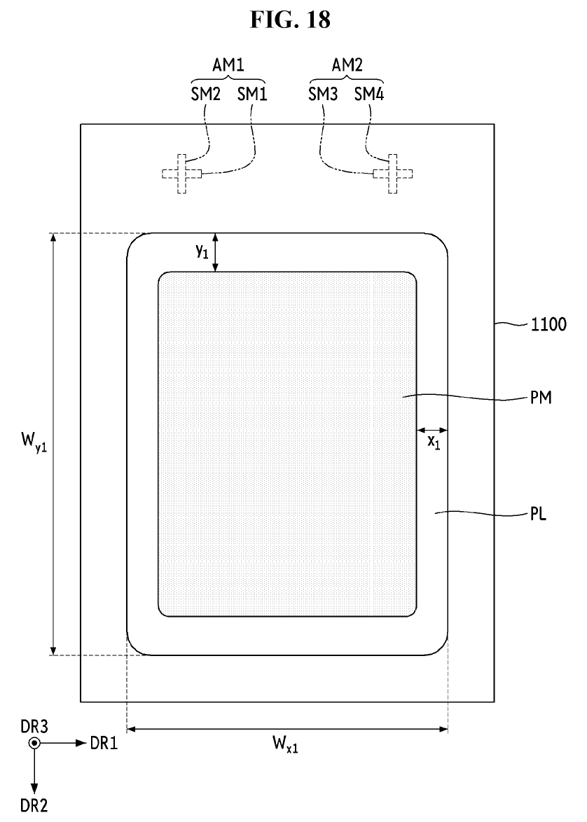

FIG. 18 is a view showing an example of a pattern map of an adhesive member applied on the polarizing plate at step S400 of FIG. 13.

Referring to FIG. 18, the pattern map PM may be created by adding/subtracting an offset to/from the size and position information of the polarizing plate PL. The offset may be determined in consideration of the viscosity of the adhesive member ADH. If the viscosity of the adhesive member ADH is high, the offset may be small. If the viscosity of the adhesive member ADH is low, the offset may be large. In FIG. 18, the offset may be x1 from the second side PL2 and the third side PL3 in the first direction DR1, and may be y1 from the first side PL1 and the fourth side PL4 in the second direction DR2.

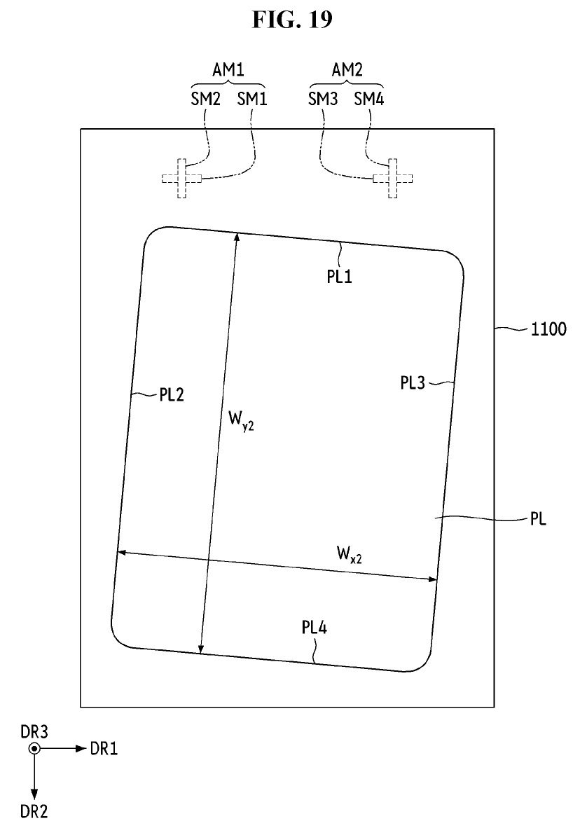

FIGS. 19-22 show a second embodiment where the size of a polarizing plate PL and the position of the polarizing plate PL relative to the stage 1100 are calculated to create a pattern map, with the polarizing plate PL not aligned on the stage 1100. The following descriptions will be focus on differences from the first embodiment; and the redundant descriptions will be omitted.

FIG. 19 is a view for illustrating data obtained by capturing the image of the polarizing plate and the stage at step S200 of FIG. 13.

As shown in FIG. 19, the length of the polarizing plate PL in the first direction DR1 is Wx2, which is the shortest distance from a second side PL2 to a third side PL3 of the polarizing plate PL. The length in the second direction DR2 is Wy2, which is the shortest distance from a first side PL1 to a fourth side PL4 of the polarizing plate PL.

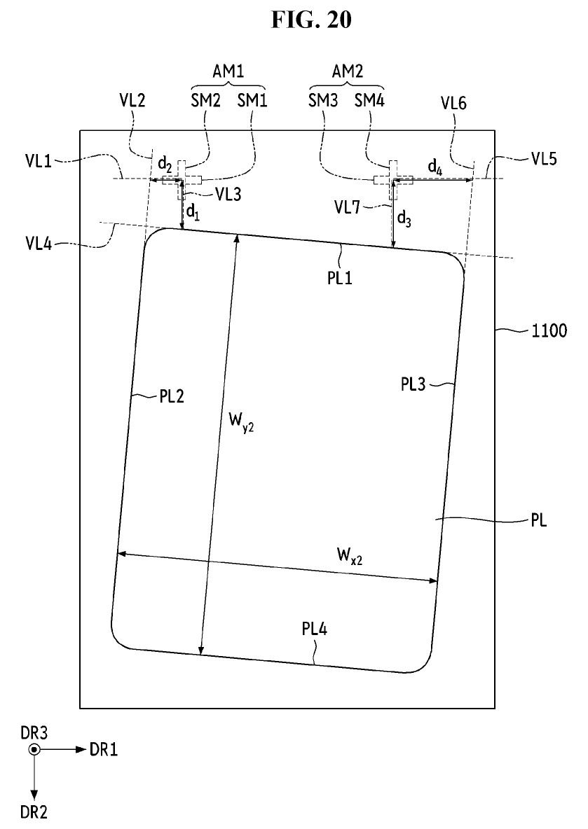

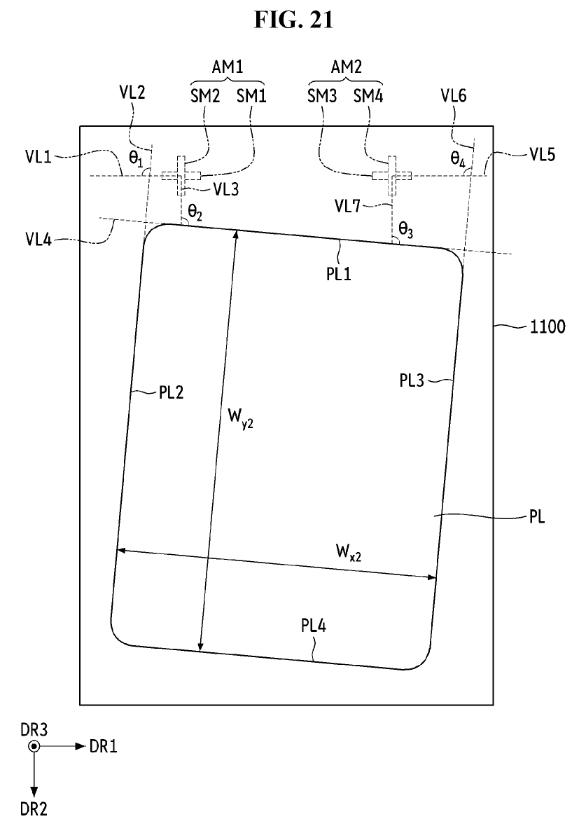

FIG. 20 is a view for illustrating calculating position information of the polarizing plate relative to the stage from the data obtained by capturing the image of the polarizing plate and the stage at step S300 of FIG. 13. FIG. 21 is a view for illustrating calculating position information of the polarizing plate relative to the stage from the data obtained by capturing the image of the polarizing plate and the stage at step S300 of FIG. 13.

Referring to FIG. 20, the pattern generating unit 1500 may measure a first distance d1 between the center of the first sub-mark SM1 and the closest first side PL1 of the line image, and a second distance d2 between the center of the second sub-mark SM2 and the closest second side PL2 of the line image. In addition, the pattern generating unit 1500 may measure a third distance d₃ between the center of the third sub-mark SM3 and the closest first side PL1 of the line image, and a fourth distance d4 between the center of the fourth sub-mark SM4 and a virtual line extended from the closest third side PL3 of the line image. In an embodiment, the first distance d₁ in the second direction DR2 may be a distance from the center of the first sub-mark SM1 to a point where a third virtual line VL3 extended from the center of the first sub-mark SM1 in the second direction DR2 and a fourth virtual line VL4 extended from the first side PL1 of the line image cross each other, the second distance d₂ in the first direction DR1 may be a distance from the center of the second sub-mark SM2 to a point where a first virtual line VL1 extended from the center of the first sub-mark SM1 in the first direction DR1 and a second virtual line VL2 extended from the second side PL2 of the line image cross each other, the third distance d₃ in the second direction DR2 may be a distance from the center of the third sub-mark SM3 to a point where a seventh virtual line VL7 extended from the center of the third sub-mark SM3 in the second direction DR2 and the fourth virtual line VL4 extended from the first side PL1 of the line image cross each other, and the fourth distance d₄ in the first direction DR1 may be a distance from the center of the fourth sub-mark SM4 to a point where a fifth virtual line VL5 extended from the center of the fourth sub-mark SM4 in the first direction DR1 and a sixth virtual line VL6 extended from the third side PL3 of the line image cross each other. Here, the center of the first sub-mark SM1 and the center of the second sub-mark SM2 are the same, and the center of the third sub-mark SM3 and the center of the fourth sub-mark SM4 are the same.

Referring to FIG. 21, the pattern generating unit 1500 may measure a first angle θ₁ formed by the first virtual line VL1 extended from the center of the first sub-mark SM1 in the first direction DR1 and the second virtual line VL2 extended from the second side PL2 of the line image, and a second angle θ₂ formed by the third virtual line VL3 extended from the center of the second sub-mark SM2 in the second direction DR2 and the fourth virtual line VL4 extended from the first side PL1 of the line image. The pattern generating unit 1500 may measure a third angle θ₃ formed by the fifth virtual line VL5 extended from the center of the third sub-mark SM3 in the first direction DR1 and the sixth virtual line VL6 extended from the third side PL3 of the line image, and a fourth angle θ₄ formed by the seventh virtual line VL7 extended from the center of the fourth sub-mark SM4 in the second direction DR2 and the fourth virtual line VL4 extended from the first side PL1 of the line image.

The pattern generating unit 1500 may calculate position information of the polarizing plate PL relative to the stage 1100 based on the first distance d1, the second distance d2, the third distance d3, the fourth distance d4, the first angle θ₁, the second angle θ₂, the third angle θ₃, and the fourth angle θ₄. In particular, the position can be accurately calculated even when the polarizing plate PL is not aligned.

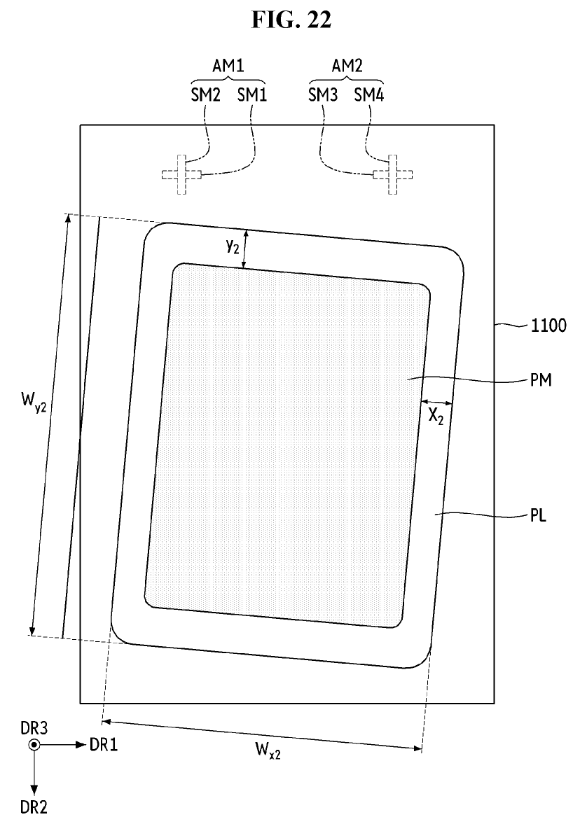

FIG. 22 is a view showing an example of a pattern map of an adhesive member applied on the polarizing plate at step S400 of FIG. 13.

In FIG. 22, the offset may be x2 from the second side PL2 and the third side PL3 in the first direction DR1, and may be y2 from the first side PL1 and the fourth side PL4 in the second direction DR2.

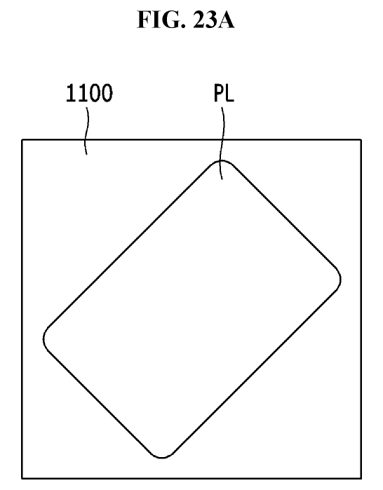

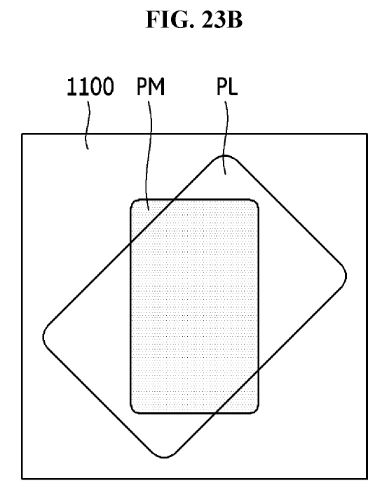

FIGS. 23A and 23B show an example of a pattern map created on a polarizing plate when there is no aligning unit in a conventional apparatus for fabricating a display device.

FIG. 23A is a view showing the polarizing plate PL placed on the stage 1100 without being aligned. FIG. 23B is a view showing a designed pattern map created on the polarizing plate in the conventional apparatus. It can be seen that the initially set pattern map PM is used regardless of the position and size of the polarizing plate PL placed on the stage 1100, and thus the position of the polarizing plate PL and the position of the pattern map PM do not match.

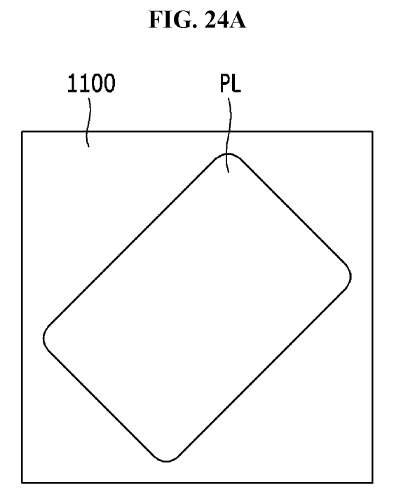

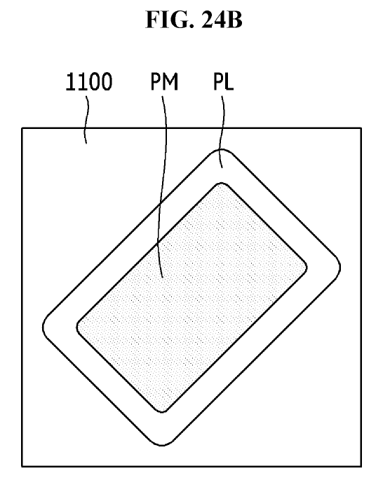

FIGS. 24A and 24B show an example of a pattern map created on a polarizing plate when there is no aligning unit in the apparatus for fabricating a display device according to the embodiment of the present disclosure.

FIG. 24A is a view showing the polarizing plate PL placed on the stage 1100 without being aligned. FIG. 24B is a view showing a pattern map PM created based on the size and position information of the polarizing plate PL in the apparatus 1000 for fabricating a display device according to the embodiment of the present disclosure. Since the pattern map PM created in consideration of the size and position of the polarizing plate PL placed on the stage 1100 is used, the appropriate pattern map PM can be created on the polarizing plate PL without any alignment.

Since the apparatus 1000 for fabricating a display device according to the embodiment of the present disclosure creates the pattern map PM based on the size of the substrate SUB and the position information of the substrate SUB relative to the stage 1100, it is possible to create the appropriate pattern map PM on the substrate SUB without an additional alignment process.

FIG. 25 is a view showing an example of ejecting an adhesive member onto the polarizing plate at step S500 of FIG. 13. FIG. 26 is a view showing an inkjet head.

Subsequently, an adhesive member ADH may be applied on the polarizing plate PL based on the pattern map PM (step S500). The adhesive member ADH may be applied as ink on the polarizing plate PL. Although an adhesive material AM is described as the ink, the present disclosure is not limited thereto. Any of a variety of materials may be employed as long as it can be applied as the ink.

Referring to FIG. 26, the body part 1321 may include an internal space that accommodates the adhesive material AM. The body part 1321 may have a shape extended in the first direction DR1. The body part 1321 may include a reservoir 1321b and a hopper 1321a.

The reservoir 1321b may accommodate the adhesive material AM. Specifically, the adhesive material AM may be accommodated in the internal space of the reservoir 1321b.

The hopper 1321a may be located between the reservoir 1321b and the stage 1100 and function as a discharger. For example, the hopper 1321a may be located on the opposite side of the reservoir 1321b in the third direction DR3. The hopper 1321a may be spatially connected to the reservoir 1321b.

The hopper 1321a may include an outlet OL opened on the opposite side in the third direction DR3. The outlet OL may have a shape extended in the first direction DR1. The outlet OL may be located such that it faces the surface of the stage 1100 in the third direction DR3.

The ejection driver 1322 may be connected to the body part 1321. The ejection driver 1322 may transmit a driving force to the body part 1321 to eject the adhesive material AM contained in the body part 1321 to the outside. For example, the ejection driver 1322 may include a syringe or a pump.

The ejection driver 1322 may provide a driving force to push the adhesive material AM of the hopper 1321a to the outside. In other words, the adhesive material AM may be ejected to the outside by the driving force provided from the ejection driver 220.

The ejection driver 1322 may assist in ejecting the adhesive material AM of the hopper 1321a to the outside. The adhesive material AM of the hopper 1321a may move toward the polarizing plate PL due to the attractive force with the polarizing plate PL. When the adhesive material AM located at the hopper 1321a moves toward the target polarizing plate PL, the ejection driver 1322 may move the ink contained in the reservoir 1321b toward the hopper 1321a.

The stirring part 1323 may be located inside the body part 1321. In some embodiments, the stirring part 1323 may include a roller extended in the first direction DR1. The stirring part 1323 may adjust the viscosity of the adhesive material AM through the rotation of the roller. For example, the roller included in the stirring part 1323 may rotate at a constant number of times per unit time to maintain the viscosity of the adhesive material AM. In addition, in order to maintain the viscosity of the adhesive material AM, the number of rotations of the roller per unit time may be increased if the viscosity of the adhesive material AM increases, and the number of rotations of the roller per unit time may be decreased if the viscosity of the adhesive material AM decreases.

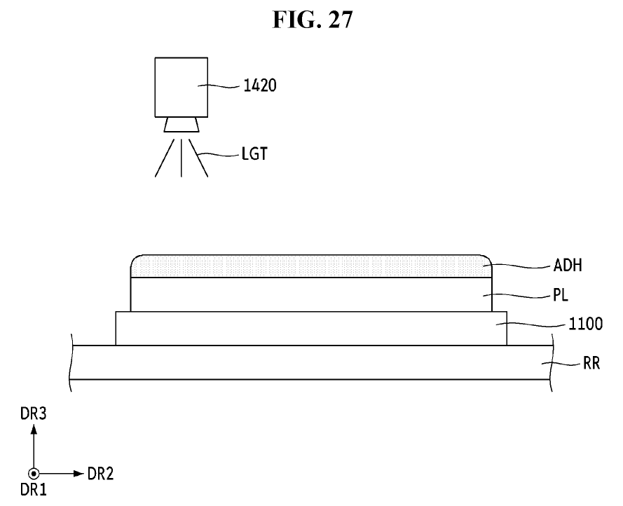

FIG. 27 is a view showing an example of preliminarily curing an adhesive member applied on a polarizing plate by irradiating it with light.

The method may further include: irradiating light onto the adhesive member ADH applied on the polarizing plate PL to preliminarily cure it. As the stage 1100 placed on the moving unit RR moves in the second direction DR2, the adhesive member ADH on the polarizing plate PL is evenly irradiated by light LGT from the light source 1420, so that preliminary curing may proceed.

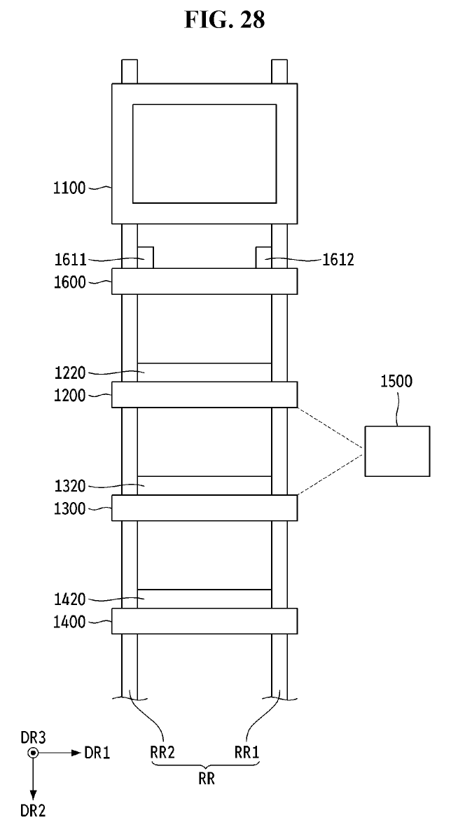

FIG. 28 is a plan view showing an apparatus for fabricating a display device according to an embodiment of the present disclosure.

An apparatus 1000 for fabricating a display device may further include an aligning unit 1600 that aligns a substrate SUB placed on the stage 1100. The aligning unit 1600 may be arranged between the stage 1100 and the sensor unit 1200. Although the aligning unit 1600 is disclosed as a separate configuration herein, the aligning unit 1600 may be included on the stage 1100. The aligning unit 1600 may include a first aligner 1611 and a second aligner 1612. The first aligner 1611 and the second aligner 1612 may be spaced apart from each other. Although two aligners 1611 and 1612 are shown herein, the number and arrangement of the aligners may vary depending on the shape or type of the substrate SUB.

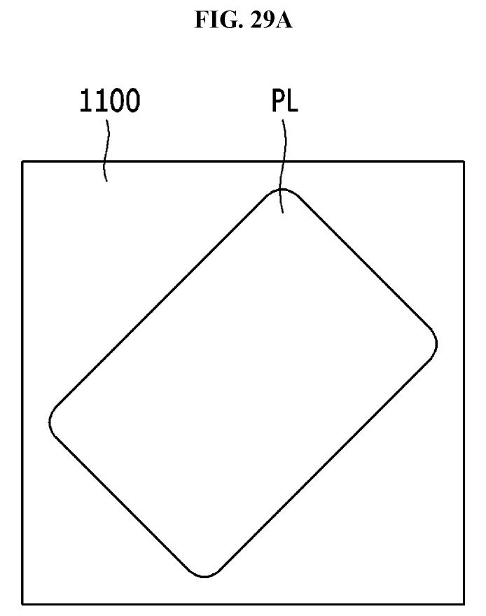

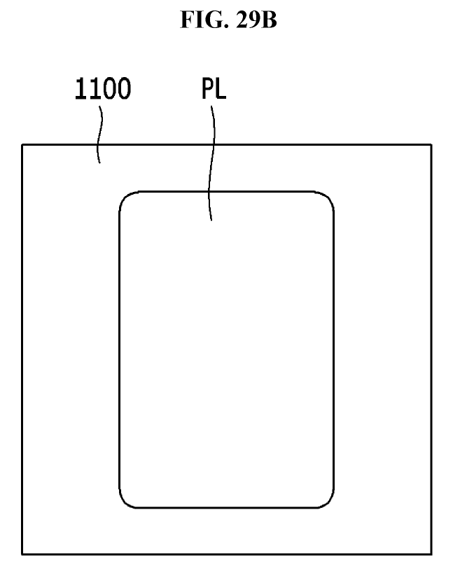

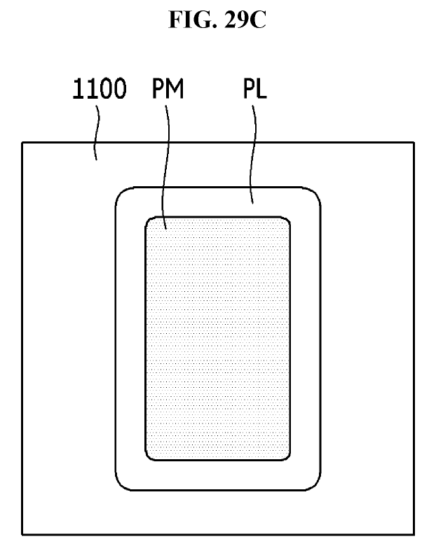

FIGS. 29A to 29C are views showing an example of a pattern map created after alignment of a polarizing plate according to an embodiment.

FIGS. 29A-29C are views showing a process of creating a pattern map PM in an apparatus 1000 for fabricating a display device including an aligning unit 1600. FIG. 29A shows a polarizing plate PL placed on the stage 1100 without being aligned. FIG. 29B shows the polarizing plate PL placed on the stage 1100 which is aligned by the aligning unit 1600. FIG. 29C shows a pattern map PM created according to the size of the aligned polarizing plate PL.

Subsequently, the polarizing plate PL on which the adhesive member ADH is applied may be attached to a surface of a display device DD (step S600). After the adhesive member ADH is preliminarily cured, the cover window CW may be attached on the polarizing plate PL.

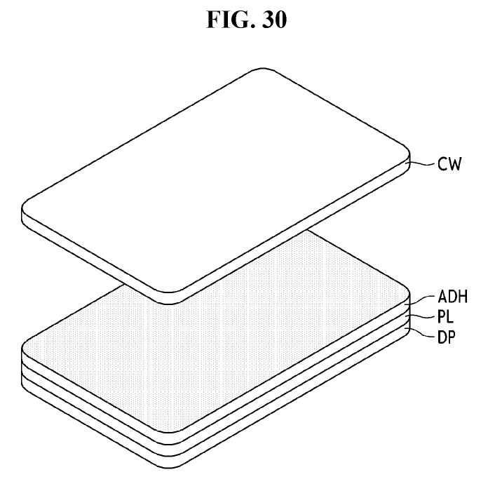

FIG. 30 is an exploded, perspective view of a display device according to an embodiment of the present disclosure.

Referring to FIG. 30, a preliminarily cured adhesive member ADH may be placed on the polarizing plate PL on the display panel DP, and the polarizing plate PL and the cover window CW may be attached together using the adhesive member ADH. By further irradiating light LGT onto the cover window CW attached on the polarizing plate PL, the adhesive member ADH between the polarizing plate PL and the cover window CW can be further cured, and thus the adhesive strength can be enhanced.

The display device according to the embodiment may be applied to a variety of electronic devices. An electronic device according to an embodiment includes the display device described above, and may further include a module or device having additional features in addition to the display device.

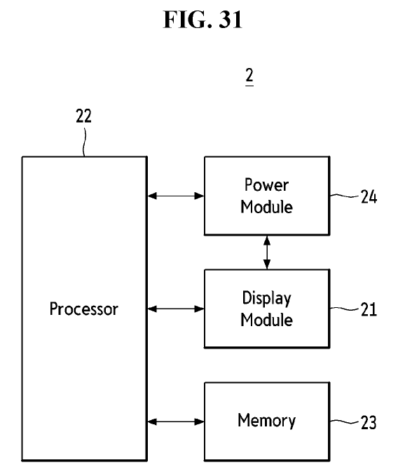

FIG. 31 is a block diagram of an electronic device according to an embodiment of the present disclosure. Referring to FIG. 31, an electronic device 2 according to an embodiment of the present disclosure may include a display module 21, a processor 22, a memory 23, and a power module 24.

The processor 22 may include at least one of: a central processing unit (CPU), an application processor (AP), a graphic processing unit (GPU), a communication processor (CP), an image signal processor (ISP), and a controller.

The memory 23 may store data information required for the operation of the processor 22 or the display module 21. When the processor 22 executes an application stored in the memory 23, an image data signal and/or an input control signal may be transmitted to the display module 21. The display module 21 may process the received signal and output image information through a display screen.

The power module 24 may include a power supply module such as a power adapter and a battery device, and a power conversion module that converts the power supplied by the power supply module to generate power required for the operation of the electronic device 20.

At least one of the elements of the electronic device 2 described above may be included in the display device 10 according to the embodiments described above. In addition, some of the individual modules functioning as a single module may be included in the display device 10 while some others may be provided separately from the display device 10. For example, the display device 10 may include the display module 21, and the processor 22, the memory 23 and the power module 24 may be provided as other devices inside the electronic device 2 than the display device 10.

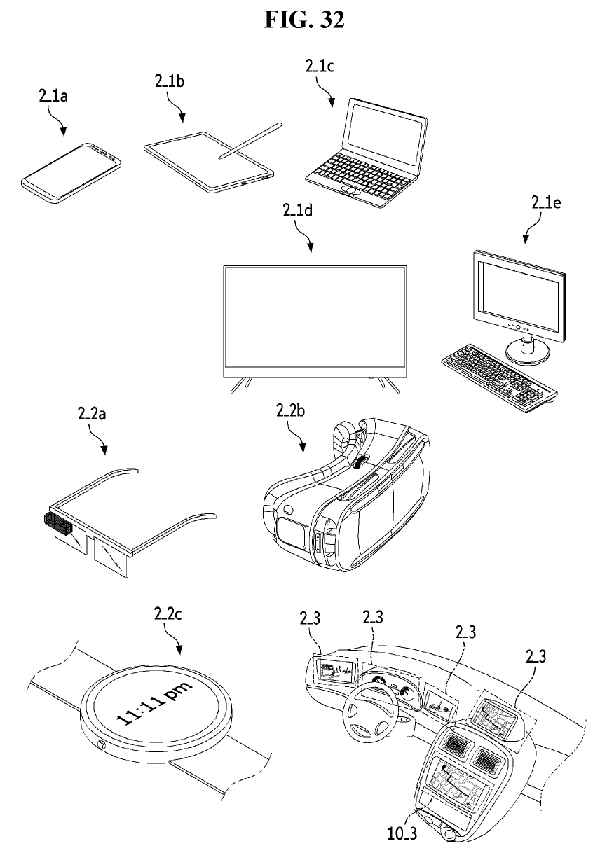

FIG. 32 is a view showing electronic devices according to a variety of embodiments of the present disclosure.

Referring to FIG. 32, a variety of electronic devices 2 employing the display devices according to the embodiments may include not only electronic devices for display images such as a smart phone 2_1a, a tablet PC 2_1b, a laptop computer 2_1c, a TV 2_1d and a desktop monitor 2_1e, but also wearable electronic devices including display modules such as smart glasses 2_2a, a head-mounted display 2_2b and a smart watch 2_2c, and electronic devices for vehicles 2_3 including display modules such as a center information display (CID) placed on the dashboard, the center fascia and the dashboard of a vehicle, and a room mirror display.

Although the embodiments of the present invention have been described with reference to the attached drawings, those skilled in the art will understand that the present invention can be implemented in other specific forms without changing the technical idea or essential features of the present invention. Therefore, it should be understood that the embodiments described above are exemplary in all respects and not restrictive.

What is claimed is:

1. An apparatus for fabricating a display device, the apparatus comprising:
a stage on which a substrate is placed;
a sensor unit, which acquires data by capturing an image of the substrate and the stage and/or measuring numerical values;
a pattern generating unit, which analyzes the data to calculate a size of the substrate and position information of the substrate relative to the stage, and creates a pattern map based on the size and position information of the substrate; and
an inkjet head unit comprising at least one inkjet head, which ejects ink onto the substrate based on the pattern map,
wherein the substrate on which the ink has been applied is attached on a surface of a display panel of the display device.

2. The apparatus of claim 1, wherein the data comprises a line image of the substrate, which is obtained by capturing an image of edges of the substrate.

3. The apparatus of claim 2, wherein the stage comprises a first alignment mark and a second alignment mark,
wherein the first alignment mark comprises a first sub-mark extended in a first direction and a second sub-mark extended in a second direction intersecting the first direction, and
wherein the second alignment mark comprises a third sub-mark extended in the first direction and a fourth sub-mark extended in the second direction.

4. The apparatus of claim 3, wherein the pattern generating unit measures a first distance between the first sub-mark and a first side of the line image, and a second distance between the second sub-mark and a second side of the line image,
and measures a third distance between the third sub-mark and the first side of the line image, and a fourth distance between the fourth sub-mark and a third side of the line image.

5. The apparatus of claim 4, wherein the pattern generating unit
measures a first angle formed by a first virtual line extended in the first direction from the first sub-mark and a second virtual line extended from the second side of the line image, and a second angle formed by a third virtual line extended in the second direction from the second sub-mark and a fourth virtual line extended from the first side of the line image, and
measures a third angle formed by a fifth virtual line extended in the first direction from the third sub-mark and a sixth virtual line extended from the third side of the line image, and a fourth angle formed by a seventh virtual line extended in the second direction from the fourth sub-mark and the fourth virtual line extended from the first side of the line image.

6. The apparatus of claim 5, wherein the position information of the substrate relative to the stage is calculated based on information of the first distance, the second distance, the third distance, the fourth distance, the first angle, the second angle, the third angle and the fourth angle.

7. The apparatus of claim 1, further comprising:
a light irradiating unit spaced apart from the inkjet head unit in a certain direction and, which irradiates light.

8. The apparatus of claim 1, further comprising:
an aligning unit located before the sensor unit and, which aligns the substrate placed on the stage.

9. The apparatus of claim 1, wherein the sensor unit comprises at least one of a line scan camera, a vision camera, and a laser camera.

10. The apparatus of claim 1, wherein pattern generating unit creates the pattern map by adding/subtracting an offset to/from the size and position information of the substrate.

11. The apparatus of claim 1, further comprising:
a stage moving unit, which moves the stage in a certain direction.

12. A method for fabricating a display device, the method comprising:
placing a substrate on a stage;
acquiring data by capturing an image of the substrate and the stage and/or measuring numerical values;
calculating a size of the substrate and position information of the substrate relative to the stage by analyzing the data;
creating a pattern map based on the size and position information of the substrate;
ejecting ink onto the substrate based on the pattern map; and
attaching the substrate on which the ink has been ejected on a surface of a display panel of the display device.

13. The method of claim 12, wherein the data comprises a line image of the substrate, which is obtained by capturing an image of edges of the substrate with a line scan camera.

14. The method of claim 13, wherein the stage comprises a first alignment mark and a second alignment mark,
wherein the first alignment mark comprises a first sub-mark extended in a first direction and a second sub-mark extended in a second direction intersecting the first direction, and
wherein the second alignment mark comprises a third sub-mark extended in the first direction and a fourth sub-mark extended in the second direction.

15. The method of claim 14, wherein the calculating the position information of the substrate relative to the stage comprises:
measuring a first distance between the first sub-mark and a first side of the line image, and a second distance between the second sub-mark and a second side of the line image; and
measuring a third distance between the third sub-mark and the first side of the line image, and a fourth distance between the fourth sub-mark and a third side of the line image.

16. The method of claim 15, wherein the calculating the position information of the substrate relative to the stage further comprises:
measuring a first angle formed by a first virtual line extended in the first direction from the first sub-mark and a second virtual line extended from the second side of the line image, and a second angle formed by a third virtual line extended in the second direction from the second sub-mark and a fourth virtual line extended from the first side of the line image; and
measuring a third angle formed by a fifth virtual line extended in the first direction from the third sub-mark and a sixth virtual line extended from the third side of the line image, and a fourth angle formed by a seventh virtual line extended in the second direction from the fourth sub-mark and the fourth virtual line extended from the first side of the line image.

17. The method of claim 16, wherein the calculating of the position information of the substrate relative to the stage further comprises:
calculating the position information of the substrate relative to the stage based on information of the first distance, the second distance, the third distance, the fourth distance, the first angle, the second angle, the third angle and the fourth angle.

18. The method of claim 12, further comprising:
after the ejecting of the ink onto the substrate, irradiating light onto the ink ejected on the substrate.

19. The method of claim 12, further comprising: prior to the acquiring of the data,
aligning the substrate.
